(19) United States
(12) Patent Application Publication
(10) Pub. No.: US 2024/0057485 A1
(43) Pub. Date: Feb. 15, 2024

(54) SYSTEMS AND METHODS FOR CONTROLLING DEVICES IN A SUPERCONDUCTING CIRCUIT

(71) Applicant: D-WAVE SYSTEMS INC., Burnaby (CA)

(72) Inventors: Fabio Altomare, North Vancouver (CA); Andrew J. Berkley, Vancouver (CA); Ilya V. Perminov, Vancouver (CA); Mauricio Reis Filho, Burnaby (CA)

(21) Appl. No.: 18/268,513

(22) PCT Filed: Dec. 16, 2021
(86) PCT No.: PCT/US2021/063899

§ 371 Date: Jun. 20, 2023

Related U.S. Application Data
(60) Provisional application No. 63/128,416, filed on Dec. 21, 2020.

(51) Int. Cl. H10N 69/00; H10N 60/12

(52) U.S. Cl. CPC H10N 69/00; H10N 60/12

(57) ABSTRACT

A system, comprising a superconducting integrated circuit and a controller, may be operated to apply, for each power level of a sequence of discrete power levels on a respective one of a plurality of power lines, one or more pulses via a respective one of a plurality of addressing lines to a respective compound Josephson junction of each of a plurality of flux storage devices of the superconducting integrated circuit to cause each of the plurality of flux storage devices to reset. Power levels may be based at least in part on an estimated worst-case asymmetry between Josephson junctions of the compound Josephson junctions. The system may be operated to partition the plurality of addressing lines into groups, and apply a respective sequence of pulses to each addressing line of each pairwise combination of groups to cause one or more of the plurality of flux storage devices to reset.

### TECHNICAL FIELD

This disclosure generally relates to systems and methods for addressing devices in a superconducting circuit, and, more specifically, to systems and methods for resetting superconducting flux storage devices and digital-to-analog converters (DAC) in superconducting integrated circuits.

### BACKGROUND

### Superconducting Integrated Circuits

Superconductivity is a set of physical properties observed in a material where electrical resistance of the material vanishes and magnetic flux fields are expelled from the material. A material exhibiting these properties is referred to in the present application as a superconductor. A material exhibiting these properties is also referred to in the present application as a superconducting material. A superconductor typically has a characteristic critical temperature below which its electrical resistance drops to zero. An electric current in a loop of superconducting material can persist indefinitely with no power source.

A superconducting integrated circuit is an integrated circuit that includes superconducting material. Superconducting material is material that becomes superconducting below a critical temperature. For example, niobium is a superconducting material that becomes superconducting below 9.2 K.

### BRIEF SUMMARY

According to an aspect, there is provided a method of operation of a system, the system comprising a superconducting integrated circuit and a controller, the superconducting integrated circuit comprising a plurality of flux storage devices, each of the plurality of flux storage devices comprising a superconducting loop interrupted by a respective compound Josephson junction, the respective compound Josephson junction comprising a respective pair of Josephson junctions, each of the plurality of flux storage devices communicatively coupled to a respective one of a plurality of addressing lines and to a respective one of a plurality of power lines, the method being performed by the controller, the method comprising estimating a worst-case asymmetry between Josephson junctions of the respective pair of Josephson junctions for the plurality of flux storage devices, estimating an average critical current for the plurality of flux storage devices, determining a starting level for current on the respective one of a plurality of power lines of each of the plurality of flux storage devices, the starting level based at least in part on the worst-case asymmetry and the average critical current, determining a power level increment, generating a sequence of discrete power levels, the sequence which includes: positive power levels between the starting level and zero, the positive power levels decrementing by the power level increment, and negative power levels between an additive inverse of the starting level and zero, the negative power levels incrementing by the power level increment, the positive and the negative power levels being alternating in the generated sequence of discrete power levels, and applying, for each power level of the sequence of discrete power levels, one or more pulses via the respective one of a plurality of addressing lines to the respective compound Josephson junction of each of the plurality of flux storage devices to cause each of the plurality of flux storage devices to reset.

According to other aspects, the method may further comprise testing the superconducting integrated circuit for reset errors, and if reset errors are detected, updating the starting level, estimating a worst-case asymmetry between Josephson junctions of the respective pair of Josephson junctions for the plurality of flux storage devices may include determining a variation of a respective critical current of each of one or more Josephson junctions in or adjacent to the superconducting integrated circuit, determining a variation of the respective critical current of each of one or more Josephson junctions in or adjacent to the superconducting integrated circuit may include determining the variation of the respective critical current of each of one or more Josephson junctions in or adjacent to the superconducting integrated circuit at room temperature, applying, for each power level of the sequence of discrete power levels, one or more pulses via the respective one of a plurality of addressing lines to the respective compound Josephson junction of each of the plurality of flux storage devices may include applying one or more pulses via a pair of addressing lines to the respective compound Josephson junction of each of the plurality of flux storage devices simultaneously, applying, for each power level of the sequence of discrete power levels, one or more pulses via the respective one of a plurality of addressing lines to the respective compound Josephson junction of each of the plurality of flux storage devices to cause each of the plurality of flux storage devices to reset may include applying, for each power level of the sequence of discrete power levels, one or more pulses via the respective one of a plurality of addressing lines to the respective compound Josephson junction of each of the plurality of flux storage devices to cause a superconducting digital-to-analog converter (DAC) to reset, applying, for each power level of the sequence of discrete power levels, one or more pulses via the respective one of a plurality of addressing lines to the respective compound Josephson junction of each of the plurality of flux storage devices to cause a superconducting DAC to reset may include applying, for each power level of the sequence of discrete power levels, one or more pulses via the respective one of a plurality of addressing lines to the respective compound Josephson junction of each of the plurality of flux storage devices to cause the superconducting DAC to reset, the superconducting DAC which may include a loop of superconducting material interrupted by an inductance, the inductance being at least one of a lumped-element inductance, a distributed inductance, a kinetic inductance, and an intrinsic inductance of the loop of superconducting material, applying, for each power level of the sequence of discrete power levels, one or more pulses via the respective one of a plurality of addressing lines to the respective compound Josephson junction of each of the plurality of flux storage devices to cause a superconducting DAC to reset, the superconducting DAC which includes a loop of superconducting material interrupted by an inductance, may include applying, for each power level of the sequence of discrete power levels, one or more pulses via the respective one of a plurality of addressing lines to the respective compound Josephson junction of each of the plurality of flux storage devices to cause the superconducting DAC to reset, the superconducting DAC may be inductively communicatively coupled to a programmable device via at least a portion of the inductance, applying, for each power level of the sequence of discrete power levels, one or more pulses via the respective one of a plurality of addressing lines to the respective compound Josephson junction of each of the plurality of flux storage devices to cause a superconducting DAC to reset may include applying, for each power level of the sequence of discrete power levels, one or more pulses via the respective one of a plurality of addressing lines to the respective compound Josephson junction of each of the plurality of flux storage devices to cause a superconducting DAC to reset, the superconducting DAC being one of a plurality of superconducting DACs, each one of the plurality of superconducting DACs communicatively coupled to a pair of addressing lines of the plurality of addressing lines, the superconducting DAC may in operation be addressable by a pair of addressing lines, each addressing lines in the pair of addressing lines may be shared with at least one other superconducting DAC, determining a starting level for current on the respective one of a plurality of power lines of each of the plurality of flux storage devices may comprise determining a starting level for current on the respective one of a plurality of power lines, each power line of the plurality of power lines may be shared with at least one other superconducting DAC, and applying, for each power level of the sequence of discrete power levels, one or more pulses via the respective one of a plurality of addressing lines to the respective compound Josephson junction of each of the plurality of flux storage devices to cause each of the plurality of flux storage devices to reset may include applying, for each power level of the sequence of discrete power levels, one or more pulses via the respective one of a plurality of addressing lines to the respective compound Josephson junction of each of the plurality of flux storage devices to cause each of the plurality of flux storage devices to reset to a ground state.

According to an aspect, there is provided a method of operation of a system, the system comprising a superconducting integrated circuit and a controller, the superconducting integrated circuit comprising a plurality of flux storage devices, each of the plurality of flux storage devices communicatively coupled to a respective pair of a plurality of addressing lines and to a respective one of a plurality of power lines, the method being performed by the controller, the method comprising partitioning the plurality of addressing lines into one or more addressing line groups, and for each pairwise combination of addressing line groups, applying a respective sequence of pulses to each addressing line of each pairwise combination of addressing line groups to cause one or more of the plurality of flux storage devices to reset.

According to other aspects, causing a flux storage device of the plurality of flux storage devices to reset may causing a superconducting digital-to-analog converter (DAC) to reset, causing a superconducting DAC to reset may include causing a superconducting DAC to reset, the superconducting DAC may include a loop of superconducting material interrupted by an inductance, the inductance may be at least one of a lumped-element inductance, a distributed inductance, a kinetic inductance, and an intrinsic inductance of the loop of superconducting material, the causing a superconducting DAC to reset, the superconducting DAC which includes a loop of superconducting material interrupted by an inductance, may include causing a superconducting DAC to reset, the superconducting DAC being inductively communicatively coupled to a programmable device via at least a portion of the inductance, causing a superconducting DAC to reset may include causing a superconducting DAC to reset to a ground state, partitioning the plurality of addressing lines into one or more addressing line groups may include determining a number m of the plurality of addressing lines to be activated simultaneously, and partitioning the plurality of addressing lines into groups of size m/2, determining a number m of the plurality of addressing lines to be activated simultaneously may include determining a number m of the plurality of addressing lines that can be activated to cause one or more flux storage devices of the plurality of flux storage devices to reset while keeping a temperature of the superconducting integrated circuit below a predetermined temperature threshold, determining a number m of the plurality of addressing lines to be activated simultaneously may include determining a number m of the plurality of addressing lines that can be activated to cause the plurality of flux storage devices to reset within a duration of time less than a predetermined duration threshold, applying a respective sequence of pulses to each addressing line of each pairwise combination of addressing line groups to cause one or more of the plurality of flux storage devices to reset may include applying the respective sequence of pulses to each addressing line of each pairwise combination of addressing line groups sequentially.

According to an aspect, there is provided a method of operation of a system, the system comprising a superconducting integrated circuit and a controller, the superconducting integrated circuit comprising a plurality of flux storage devices, each of the plurality of flux storage devices communicatively coupled to at least one of a plurality of addressing lines and to a respective one of a plurality of power lines, the method being performed by the controller, the method comprising determining, by the controller, a first subset of the plurality of addressing lines and a second subset of the plurality of power lines, and causing a flux storage device of the plurality of flux storage devices to reset by activating, by the controller, the first subset of the plurality of addressing lines and the second subset of the plurality of power lines simultaneously.

According to other aspects, causing a flux storage device of the plurality of flux storage devices to reset may include causing a superconducting digital-to-analog converter (DAC) to reset, causing a superconducting DAC to reset may include causing a superconducting DAC to reset, the superconducting DAC which may include a loop of superconducting material interrupted by an inductance, the inductance may be at least one of a lumped-element inductance, a distributed inductance, a kinetic inductance, and an intrinsic inductance of the loop of superconducting material, causing a superconducting DAC to reset, the superconducting DAC which includes a loop of superconducting material interrupted by an inductance, may include causing a superconducting DAC to reset, the superconducting DAC, the superconducting DAC may be inductively communicatively coupled to a programmable device via at least a portion of the inductance, and causing a superconducting DAC to reset may include causing a superconducting DAC to reset to a ground state.

In other aspects, the features described above may be combined together in any reasonable combination as will be recognized by those skilled in the art.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn, are not necessarily intended to convey any information regarding the actual shape of the particular elements, and have been solely selected for ease of recognition in the drawings.

FIG. 1 is a schematic diagram of an example implementation of a superconducting DAC, according to the present disclosure.

FIG. 2A is a plot of an example time-dependent signal applied to a power line of a DAC, according to the present disclosure.

FIG. 2B is a plot of an example time-dependent signal applied to a compound Josephson junction (CJJ) loop of a DAC, according to the present disclosure.

FIG. 3A is a plot of an example sequence of current and flux changes during reset of a DAC, according to the present disclosure.

FIG. 3B is a plot of another example sequence of current and flux changes during reset of a DAC, according to the present disclosure.

FIG. 3C is a flow chart of an example implementation of a method for resetting a set of DACs in a superconducting integrated circuit, according to the present disclosure.

FIG. 4 is a schematic diagram of an example implementation of a DAC array, according to the present disclosure.

FIG. 5A is a plot of an example time-dependent signal applied to respective power lines of each DAC of a pair of DACs, according to the present disclosure.

FIG. 5B is a plot of an example time-dependent signal applied to respective CJJ loops of each DAC of the same pair of DACs referred to in FIG. 5B, according to the present disclosure.

FIG. 6A is a plot of example time-dependent signals applied to respective power lines of each DAC of a pair of DACs (DAC1 and DAC2), according to the present disclosure.

FIG. 6B is a plot of an example time-dependent signal applied to a CJJ loop of a first DAC (DAC1) of the same pair of DACs referred to in FIG. 6A, according to the present disclosure.

FIG. 6C is a plot of an example time-dependent signal applied to a CJJ loop of a second DAC (DAC2) of the same pair of DACs referred to in FIGS. 6A and 6B, according to the present disclosure.

FIG. 7A is a plot of an example time-dependent signal applied to a power line of a DAC, according to the present disclosure.

FIG. 7B is a plot of an example time-dependent signal applied to a CJJ loop of the same DAC referred to in FIG. 7A, according to the present disclosure.

FIG. 8A is a plot of example time-dependent signals applied to respective power lines of each DAC (DAC1 and DAC2) of a pair of DACs, according to the present disclosure.

FIG. 8B is a plot of an example time-dependent signal applied to addressing lines (ADDR and TRIG) of DAC1 referred to in FIG. 6A, according to the present disclosure.

FIG. 8C is a plot of an example time-dependent signal applied to addressing lines (ADDR and TRIG) of DAC2 referred to in FIGS. 6A and 6B, according to the present disclosure.

FIG. 9A is a flowchart of an example method for resetting a set of DACs in a superconducting integrated circuit, according to the present disclosure.

FIG. 9B is a table of an example pulse sequence for the distributed annealing reset procedure of FIG. 9A, according to the present disclosure.

FIG. 10A is a flowchart of another example method for resetting a set of DACs in a superconducting integrated circuit, according to the present disclosure.

FIG. 10B is a table of an example pulse sequence for the distributed annealing reset procedure of FIG. 10A, according to the present disclosure.

FIG. 11 is a schematic diagram of an exemplary computing system including a digital computer and an analog computer, in accordance with the present disclosure.

### DETAILED DESCRIPTION

### Preamble

In the following description, some specific details are included to provide a thorough understanding of various disclosed implementations and embodiments. One skilled in the relevant art, however, will recognize that embodiments may be practiced without one or more of these specific details, or with other methods, components, materials, etc. In other instances, well-known structures associated with superconductive devices and integrated superconductive circuits have not been shown or described in detail to avoid unnecessarily obscuring descriptions of the implementations or embodiments of the present methods. Throughout this specification and the appended claims, the words “element” and “elements” are used to encompass, but are not limited to, all such structures, systems, and devices associated with superconductive circuits and integrated superconductive circuits.

Unless the context requires otherwise, throughout the specification and claims which follow, the word “comprise” is synonymous with “including,” and is inclusive or open-ended (i.e., does not exclude additional, unrecited elements or acts).

Reference throughout this specification to “one embodiment” “an embodiment”, “another embodiment”, “one example”, “an example”, “another example”, “one implementation”, “another implementation”, or the like means that a particular referent feature, structure, or characteristic described in connection with the embodiment, example, or implementation is included in at least one embodiment, example, or implementation. Thus, the appearances of the phrases “in one embodiment”, “in an embodiment”, “another embodiment” or the like in various places throughout this specification are not necessarily all referring to the same embodiment, example, or implementation. Furthermore, the particular features, structures, or characteristics may be combined in any suitable manner in one or more embodiments, examples, or implementations.

It should be noted that, as used in this specification and the appended claims, the singular forms “a,” “an,” and “the” include plural referents unless the content clearly dictates otherwise. Thus, for example, reference to a readout system including “a superconducting resonator” includes a single superconducting resonator, or two or more superconducting resonators. It should also be noted that the term “or” is generally employed in its sense including “and/or” unless the content clearly dictates otherwise.

The headings provided herein are for convenience only and do not interpret the scope or meaning of the embodiments.

### Superconducting Flux Storage Devices

A superconducting integrated circuit (also referred to in the present application as a superconducting chip) can include a quantum processor, for example. A quantum processor can include a plurality of qubits and at least one coupling device that communicatively couples at least a pair of the plurality of qubits. Qubits and coupling devices can be controlled by adjusting a number of control parameters. In some implementations, a qubit can have six control parameters, and a coupling device can have a single control parameter.

If the number of devices on a superconducting integrated circuit is sufficiently small, they can be controlled by dedicated analog lines driven by electronics situated at room temperature. In the case of a quantum processor with many tens, hundreds, or thousands of devices, it can become impractical to use analog lines, and desirable to implement control circuitry on the superconducting chip.

A superconducting quantum processor, for example, can be programmed by static flux biases applied to superconducting loops in qubits and coupling devices of the superconducting quantum processor. Desired values of the static flux biases can be programmed into on-chip control devices using a relatively small number of control lines that carry digital signals generated at room temperature.

The on-chip control devices can include superconducting flux storage devices such as superconducting digital-to-analog converters (DACs) (also referred to in the present application as flux DACs). Flux DACs can combine functions of persistent memory and digital-to-analog conversion. In some implementations, a flux DAC has dimensions of the order of 10 μm. Having several flux DACs attached to a single qubit in a quantum processor can set a lower bound on qubit size, and can influence possible qubit shapes, hardware graph topologies, and processor architecture.

### XYZ-Addressing of Flux DACs

In an example implementation of a quantum processor, 512 qubits and associated coupling devices can be controlled by 4608 flux DACs. An XYZ-addressing approach can control the quantum processor using only 56 lines. The processor can be arranged as an 8×8 array of tiles, each tile having 72 flux DACs. The flux DACs of each tile can be arranged in a respective 3-DAC plaquette. One of each set of three DACs in a 3-DAC plaquette can be selected using one of three lines (referred to in the present application an address (ADDR) line), all three sharing another line (referred to in the present application as a trigger (TRIG) line), in an arrangement that uses 15 ADDR lines and 5 TRIG lines to address DACs in the tile. The 8×8 array of tiles can be divided into 16 domains (referred to in the present application as power (PWR) domains), and arranged such that 4608 flux DACs can be addressed using 30 ADDR lines, 10 TRIG lines, and 16 PWR lines in total. See for example Bunyk P. et al., “ARCHITECTURAL CONSIDERATIONS IN THE DESIGN OFA SUPERCONDUCTING QUANTUM ANNEALING PROCESSOR”, arXiv:1401.5504v1, 21 January 2014.

Other examples of addressing approaches for DACs can be found in U.S. Pat. No. 10,528,886 and United States Patent Application Publication No. 2021/0190885,

### Josephson Junction Asymmetry in DACs

The present technology includes systems and methods for resetting one or more flux storage devices (for example, flux DACs) in a superconducting integrated circuit. Resetting a flux storage device can include returning the device to a ground state.

In some implementations, the flux storage device includes one or more Josephson junctions. The Josephson junctions may be compound or compound-compound Josephson junctions. A compound Josephson junction (CJJ) includes two electrically parallel current paths each interrupted by at least one Josephson junction. A compound-compound Josephson junction (CCJJ) is a compound Josephson junction that includes two electrically parallel current paths, at least one of which is interrupted by at least one compound Josephson junction.

Asymmetry in a pair of constituent Josephson junctions, e.g., in a pair of Josephson junctions each of which interrupts a respective electrically parallel current path of a compound Josephson junction of the flux storage device, can lead to resetting the storage device to a state other than a ground state. Resetting the storage device to a state other than a ground state can cause a decrease in the number of pulses able to be stored in the storage device. For at least this reason, resetting the flux storage device to the ground state can be advantageous.

Resetting a flux storage device can include transmitting a series of current and flux pulses to the flux storage device. Resetting a flux storage device can include repeating a transmission of a series of current and flux pulses for each power level of a plurality of power levels. The power levels can be determined based at least in part on a circulating current in a flux storage device. Each repetition can reset a respective population of flux storage devices characterized by a respective junction asymmetry.

A superconducting quantum processor may include one or more flux storage devices. In some implementations, the flux storage devices are DACs. In some implementations, the superconducting quantum processor includes a superconducting integrated circuit, and the superconducting integrated circuit includes a number of on-chip DACs.

An on-chip DAC includes at least one DAC stage. In some implementations, an input signal to an on-chip DAC can be represented in binary form (i.e., using only binary numbers “0” and “1”). If each DAC stage of an on-chip DAC has only two states (e.g., “0” and “1”), then a resolution of the on-chip DAC can be expressed in terms of a number of stages. For example, an 8-stage DAC can store 2⁸=256 discrete values. While the following description refers to single-stage DACs, the present technology can be applied to each stage of a multi-stage DAC. In particular, it will be understood that while the description below refers to resetting a DAC or sharing lines between DACs, this language also equally encompasses different stages of the same multi-stage DAC.

On-chip DACs can be used in the operation of a superconducting quantum processor, for example. A typical scenario in the operation of a superconducting quantum processor can include a) an initialization of the superconducting quantum processor, and b) an evolution of the superconducting quantum processor. The initialization of the superconducting quantum processor can include an initialization of a number of DACs. The initialization of the DACs can include initializing the DACs to an initial state, e.g., a ground state. Initializing the DACs is also referred to in the present application as resetting the DACs. The evolution of the superconducting quantum processor can include programming a number of the DACs to a state different from the initial state. The evolution of the superconducting quantum processor is also referred to in the present application as annealing. However, it will be understood that other types of evolutions may be performed with a quantum processor, such as, for example, the evolution of a series of gates on one or more qubits in a gate model processor.

### Annealing Reset

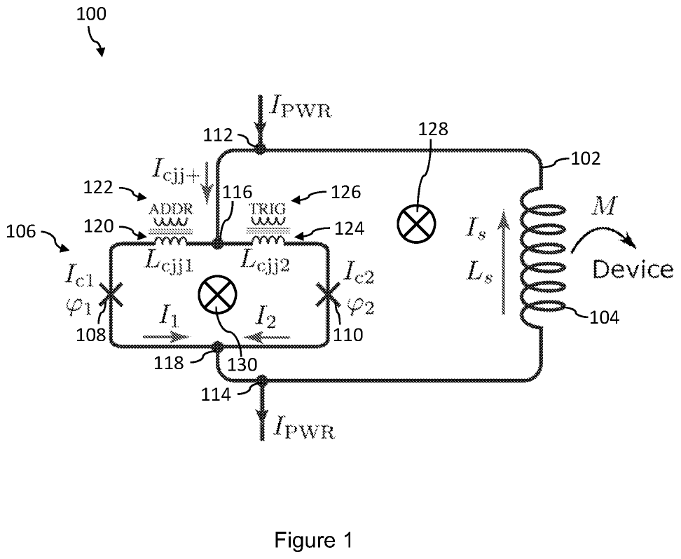

FIG. 1 is a schematic diagram of an example implementation of a superconducting DAC 100, according to the present disclosure. Superconducting DAC 100 may be an element of an input/output system. The input/output system may be an element of a quantum computer or a hybrid digital/quantum computer system. The input/output system may write data to a quantum processor, and read data from a quantum processor.

DAC 100 includes a superconducting loop 102. Superconducting loop 102 can include or consist of a superconducting material. The superconducting material may be a superconducting metal, e.g., niobium, aluminum, and the like. Superconducting loop 102 can be used to store flux. Flux can be loaded into superconducting loop 102 of DAC 100 in multiples of magnetic flux quanta.

Superconducting loop 102 of DAC 100 is interrupted by an inductance 104. Inductance 104 may be a lumped-element inductance, a distributed inductance, a kinetic inductance, an intrinsic inductance of loop 102, or a combination of the above. DAC 100 can be inductively communicatively coupled to a device (not shown in FIG. 1) by inductance 104 and a mutual inductance M. The device may be a programmable device. The device may be a tunable device. The device may be a qubit or a coupling device, for example.

Superconducting loop 102 of DAC 100 is also interrupted by a compound Josephson junction (CJJ) 106. CJJ 106 includes two electrically parallel superconducting paths, each of the two parallel superconducting paths interrupted by a respective Josephson junction 108 and 110.

A power line (also referred to in the present application as a PWR line or simply PWR) is superconductingly electrically communicatively coupled to superconducting loop 102 of DAC 100 at nodes 112 and 114. Current enters from the PWR line at node 112, and leaves superconducting loop 102 at node 114.

CJJ 106 interrupts superconducting loop 102 between nodes 116 and 118. An inductance 120 between node 116 and Josephson junction 108 is inductively communicatively coupled to an ADDR line 122. An inductance 124 between node 116 and Josephson junction 110 is inductively communicatively coupled to a TRIG line 126. ADDR and TRIG lines 122 and 126 are addressing lines. See, for example, a description of XYZ-addressing of flux DACs earlier in the present application. ADDR and TRIG lines, as well as PWR lines, may be collectively referred to as control lines. Arrow ends 128 and 130 show a direction of flux in superconducting loop 102 and CJJ 106, respectively, into the plane of the FIG. 1.

In some implementations of DAC 100, Josephson junctions 108 and 110 are asymmetric. Junction asymmetry refers to a difference in critical currents between a pair of Josephson junctions. Junction asymmetry may refer to a difference in critical currents between a pair of Josephson junctions in a compound Josephson junction, for example, Josephson junctions 108 and 110.

A difference in critical currents between a pair of Josephson junctions may at least in part depend on a difference in size between the Josephson junctions. In other implementations, the Josephson junctions may have different critical currents while being at least approximately the same size. Asymmetry may be caused, for example, during fabrication. In some implementations, junction asymmetry may be intentionally introduced, while in other implementations junction asymmetry may be unintentional and result, for example, from limits on the precision of fabrication techniques or introduced by natural variations in materials or contamination of fabrication equipment.

In the present application, a CJJ with an asymmetry in the Josephson junctions of the CJJ refers to a CJJ that includes two electrically parallel current paths, each parallel current path interrupted by a respective Josephson junction, in which the critical current of a Josephson junction interrupting one of the two parallel current paths of the CJJ is not the same as the critical current of a Josephson junction interrupting the other of the two parallel current paths of the CJJ.

Critical current has a specific meaning with respect to a Josephson junction that would be known to one of ordinary skill in the art. Equations governing the dynamics of a Josephson junction and the Josephson effect include the following:

$$U ( t ) = \frac{ℏ}{2 e} \frac{\partial φ}{\partial t}$$

The above equation can be referred to as the superconducting phase evolution equation and relates the voltage U(t) across a Josephson junction to the change in phase difference φ(t) across the Josephson junction.

I(t)=I_{C}sin φ(t)

The above equation can be referred to as the Josephson or weak-link current-phase relation, and describes the current I(t) through the Josephson junction.

The current I_{C} is a constant referred to as the critical current of the Josephson junction. These equations can be found, for example, in Barone, A., and Paterno, G., Physics and Applications of the Josephson Effect, (1982), John Wiley & Sons, ISBN 978-0-471-01469-0. The critical current is the current in a superconductive material above which the material is normal (i.e., not superconducting) and below which the material is superconducting, at a specified temperature and in the absence of external magnetic fields. See, for example, Critical Current. (n.d.) McGraw-Hill Dictionary of Scientific & Technical Terms, 6E. (2003) (retrieved Oct. 23 2018 from https://encyclopedia2.thefreedictionary.com/Critical+Current.)

Junction asymmetry may, in some instances, be undesirable. Junction asymmetry may, for example, cause uncertainty in an initialization of a DAC having a CJJ with asymmetric constituent Josephson junctions. Uncertainty in an initialization of a DAC may lead to the DAC being initialized in a state other than a desired state (e.g., in a state other than a ground state). Uncertainty in the initialization of the DAC may lead to an error in an evolution of the superconducting quantum processor (whether or not the evolution includes a programming of the DAC to a state different from the initial state).

One approach to eliminating or at least reducing reset errors (e.g., reset errors caused by junction asymmetry) is to test the bits of each DAC for reset errors. A disadvantage of this approach is that it can be time-consuming. It takes time to perform each test, and there can be a large number of DACs to test.

The present technology can decrease the time taken to eliminate or at least reduce reset errors. The present technology includes transmission of a predetermined sequence of pulses to the on-chip DAC which reliably resets the DAC to an initial state, such as a ground state even in the presence of junction asymmetry. In practice, a degree of junction asymmetry is likely to be present in most DACs.

The technology described in the present application can be used to reliably reset a DAC when a) an accuracy with which a current in a control line (e.g., the PWR line) can be configured is at least one order of magnitude larger than a change in circulating current in a body of the DAC, the change in circulating current caused by a change of one flux quantum in flux stored in the DAC, and b) the change in circulating current is at least one order of magnitude larger than i) noise in the body of the DAC, and ii) an effective temperature reached by the DAC due to thermal energy liberated while exceeding a DAC critical current.

In some implementations of the systems and methods described below, on-chip DACs having an asymmetry as high as 10% can be reset. Furthermore, the present technology may be used in combination with testing and recovery of specific devices, for example, in the case of devices having an exceptionally high degree of asymmetry. Resetting DACs refers to initializing all of the DACs to the same initial state, or an initial state having the same value to a predetermined required precision. In some implementations this may be a ground state, although it will be understood that other initial states may be used.

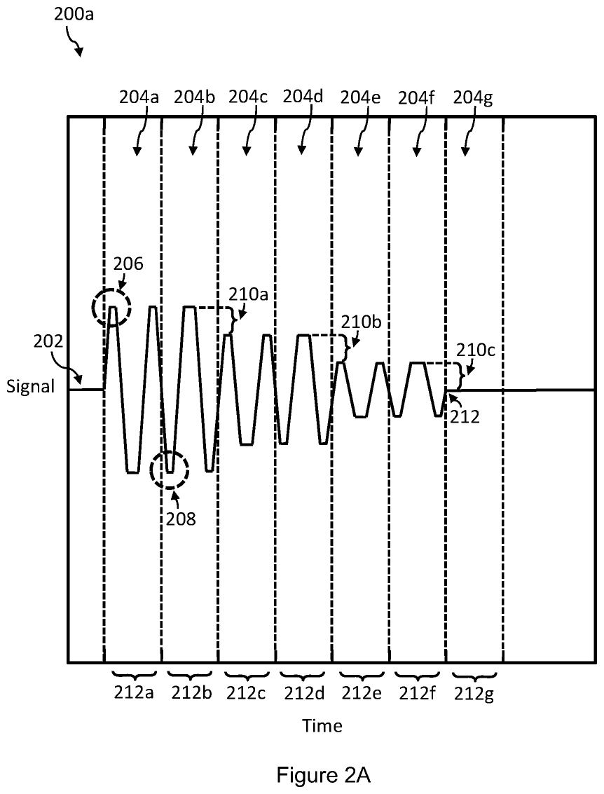

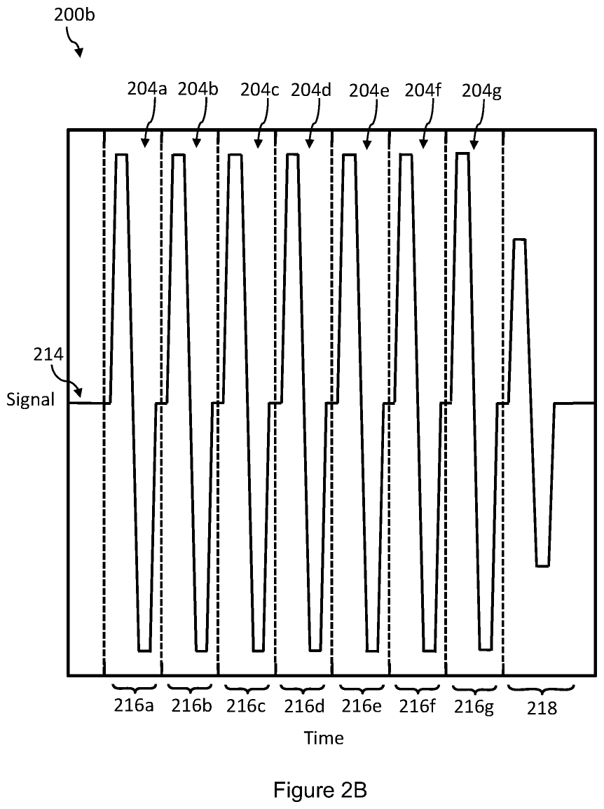

FIG. 2A is a plot 200a of an example time-dependent signal 202 applied to a power line of a DAC, according to the present disclosure. Signal 202 can be a current applied to a body of the DAC.

FIG. 2B is a plot 200b of an example time-dependent signal 214 applied to a CJJ loop of a DAC (for example, superconducting DAC 100 of FIG. 1), according to the present disclosure. Signal 214 may be applied to the CJJ loop by one or both of the addressing lines (ADDR and TRIG lines 122 and 126 of FIG. 1, for example). In normal operation, signal 214 is applied to the CJJ loop typically by both the addressing lines. Signal 214 can be proportional to a total flux applied to the CJJ loop. In some implementations, the signals applied to the ADDR and TRIG lines can be the same as each other. In other implementations, the signals applied to the ADDR and TRIG lines differ from each other only in sign.

Plots 200a and 200b of FIGS. 2A and 2B, respectively, include seven time intervals 204a, 204b, 204c, 204d, 204e, 204f, and 204g (collectively referred to as time intervals 204). Adjacent time intervals of time intervals 204 are delineated from one another by vertical dashed lines. The polarity of signal 202 reverses from one time interval to the next. For example, peak current 206 in time interval 204a is positive, and peak current 208 in time interval 204b is negative.

The peak current can vary from one time interval to another. For example, there is a change 210a in peak current from time interval 204b to time interval 204c, a change 210b in peak current from time interval 204d to time interval 204e, and a change 201c in peak current from time interval 204f to time interval 204g. In some implementations, at least two of the changes (e.g., two of changes 210a, 210b, and 210c) can be the same. In some implementations, changes 210a, 210b, and 210c are the same as each other.

Plot 200a of FIG. 2A is an example sequence of power currents from a maximum I_{MAX} at peak current 206 to zero at point 212. In some implementations, changes 210a, 210b, and 210c are the same, and can be denoted by Δ_{PWR}. At each time interval, a respective set of pulses can be applied to a CJJ loop of the DAC. In some implementations, the respective set of pulses consists of a single pulse. The shapes of pulses in the set of pulses in FIGS. 2A and 2B are example shapes. In other implementations, various other shapes are used. The peak amplitude of each set of pulses may vary from one set to another. In some implementations, for each power current, each set of pulses includes a respective negative peak at least approximately equal in magnitude to a respective positive peak.

Plot 200a of FIG. 2A includes a set of seven pulses 212a, 212b, 212c, 212d, 212e, 212f, and 212g of varying amplitude. In an example implementation, e.g., the implementation depicted in FIG. 2A, the amplitudes of the set of seven pulses (i.e., the peak values of I_{PWR} in time intervals 204) have the following sequence of values (+0.45, −0.45, +0.3, −0.3, +0.15, −0.15, 0.0).

The first value in the sequence is also referred to in the present application as a starting level.

Plot 200b of FIG. 2B includes a set of seven pulses 216a, 216b, 216c, 216d, 216e, 216f, and 216g of at least approximately equal amplitude. Plot 200b includes an additional pulse 218 of lower amplitude after the end of time interval 204g. Additional pulse 218 can cause a final state of a DAC to be stable. For example, additional pulse can cause the final state of the DAC to be a full-flux quantum (Φ₀) state in superconducting loop 102. A half-flux quantum (Φ₀/2) state in superconducting loop 102 can be an intermediate state used for resetting and programming of the DAC. A half-flux quantum state can be stable when the number of pulses in the DAC is low, and can become progressively more unstable as the number of pulses increases.

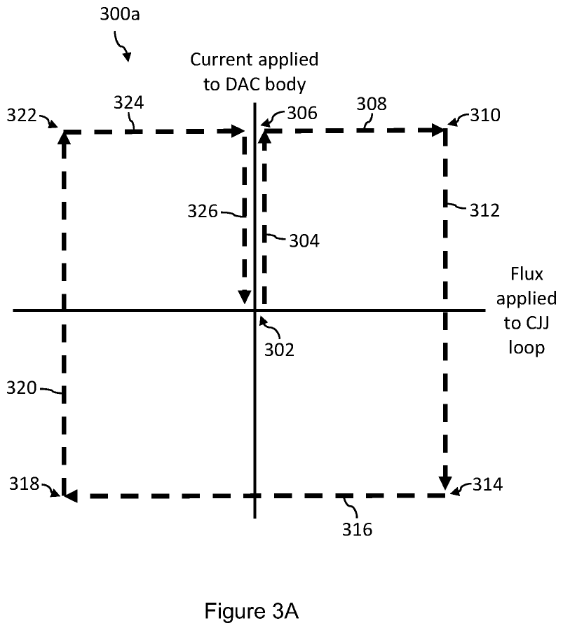

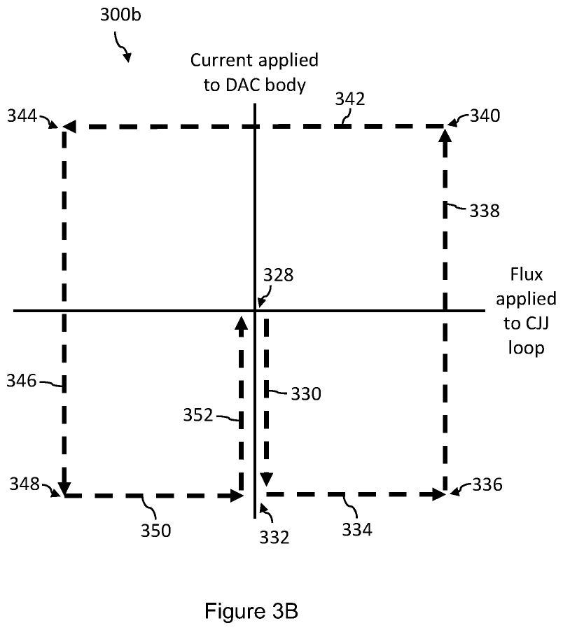

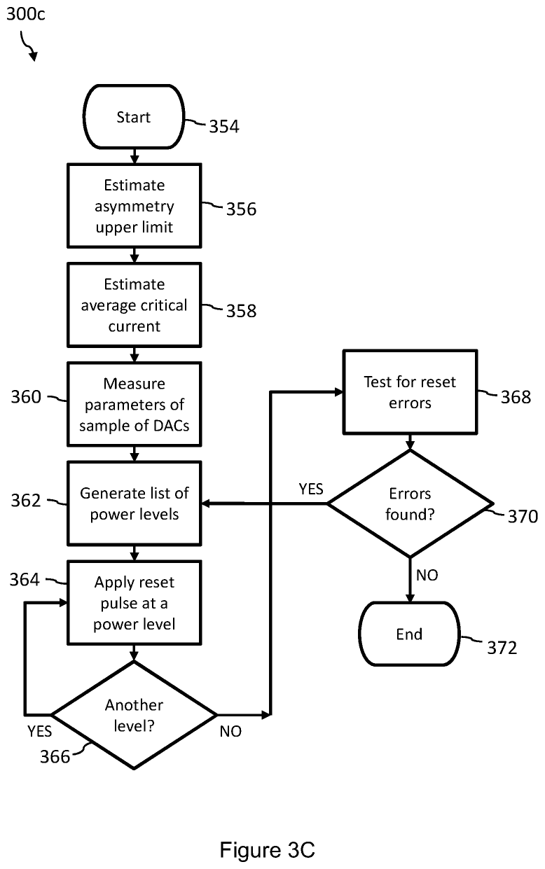

FIG. 3A is a plot 300a of stationary level for a positive power line current, according to the present disclosure. Positions on plot 300a are referred to as coordinates. Coordinates can be operating points of a flux DAC (e.g., superconducting DAC 100 of FIG. 1). For a given power level, both power current and flux are initialized to zero at coordinate 302 (0,0). The power current is increased to +I_{MAX} along trajectory 304 (0, I_{PWR}) to coordinate 306 (0, +I_{MAX}). The flux is increased to +Φ_{MAX} along trajectory 308 (Φ, +I_{MAX}) to coordinate 310 (+Φ_{MAX}, +I_{MAX}). The power current is decreased to −I_{MAX} along trajectory 312 (+Φ_{MAX}, I_{PWR}) to coordinate 314 (+Φ_{MAX}, −I_{MAX}). The flux is decreased to −Φ_{MAX} along trajectory 316 (Φ, I_{MAX}) to coordinate 318 (−Φ_{MAX}, −I_{MAX}). The power current is increased to +I_{MAX} along trajectory 320 (−Φ_{MAX}, −I_{MAX}) to coordinate 322 (−Φ_{MAX}, +I_{MAX}). The flux is increased to zero along trajectory 324 (Φ, +I_{MAX}) to coordinate 306 (0, +I_{MAX}) . Finally, the power current is returned to zero along trajectory 326 (0, I_{PWR}) to coordinate 302 (0,0).

FIG. 3B is a plot 300b of a stationary level for a negative power line current, according to the present disclosure. Positions on plot 300b are referred to as coordinates. Coordinates can be operating points of a flux DAC (e.g., superconducting DAC 100 of FIG. 1). For a given power level, both power current and flux are initialized to zero at coordinate 328 (0,0). The power current is decreased to −I_{MAX} along trajectory 330 (0, I_{PWR}) to coordinate 332 (0, −I_{MAX}). The flux is increased to +Φ_{MAX} along trajectory 334 (Φ, −I_{MAX}) to coordinate 336 (+Φ_{MAX}, −I_{MAX}). The power current is increased to +I_{MAX} along trajectory 338 (+Φ_{MAX}, I_{PWR}) to coordinate 340 (+Φ_{MAX}, +I_{MAX}). The flux is decreased to −Φ_{MAX} along trajectory 342 (Φ, +I_{MAX}) to coordinate 344 (−Φ_{MAX}, +I_{MAX}). The power current is decreased to −I_{MAX} along trajectory 346 (−Φ_{MAX}, I_{PWR}) to coordinate 348 (−Φ_{MAX}, −I_{MAX}). The flux is increased to zero along trajectory 350 (Φ, −I_{MAX}) to coordinate 332 (0, −I_{MAX}). Finally, the power current is returned to zero along trajectory 352 (0, I_{PWR}) to coordinate 328 (0,0).

The circulating current in a superconducting DAC can depend on a flux state of the DAC, the flux state being the number of flux quanta stored in the main loop. A change in the flux state of the DAC by a single pulse can be expressed as being equivalent to a change in the circulating current given by:
[symbol] =Φ₀/L_{BODY} where Φ₀ is a magnetic flux quantum, and L_{BODY} is an inductance of the DAC which can be expressed as follows:
L_{BODY}=Lₛ+L_{cjj1}L_{cjj2}/(L_{cjj1}+L_{cjj2}) where Lₛ is inductance 104 of FIG. 1, L_{cjj1} is inductance 120 of FIG. 1, and L_{cjj2} is inductance 124 of FIG. 1.

The CJJ of the DAC includes two parallel current paths, each path interrupted by a respective one of a pair of Josephson junctions. An asymmetry between the Josephson junctions of the pair of Josephson junctions can be expressed in terms of a current I_{ASYM} as follows:
I_{ASYM}=γ(I_{C1}+I_{C2}) where γ is a degree of asymmetry, and I_{C1} and I_{C2} are critical currents of each of the Josephson junctions.

During each of time intervals 204, a current applied to the power line can be compared with the following currents representative of the DAC state after it has been programmed:

$$+ = {nI}_{} + {I}_{A S Y M}$$

$${I}_{}$$

$$- = {nI}_{} - {I}_{A S Y M}$$

$${I}_{}$$

Since, in general, the state of a DAC may not be known, the case n>0 (where n is representative of the state of the DAC) can be handled in a reset signal when the peak current applied to the power line is positive. Similarly, the case n<0 can be handled when the peak current is negative. In the following we will discuss only the n>0 case:

An example is time interval 204a of FIG. 2A where a first peak is positive, and a peak current Iₚₑₐₖ is peak current 206. Behaviour of the superconducting integrated circuit can be as follows:
1. When [symbol] , the DAC will not change state.
2. When [symbol] , the DAC will move toward a ground state. The final state will depend on the asymmetry, and the DAC will be in a final state characterized by a number of flux quanta [symbol] . Additionally, where I_{ASYM}≈m [symbol] , the final state of the DAC can probabilistic and not deterministic. For example, the DAC can be in a final state characterized by either m or (m−1) flux quanta. To obtain more consistent results during operation of the superconducting integrated circuit, it is desirable for the DACs to be reset to the ground state or at least to the same state.
3. When [symbol] , the DAC will move toward the ground state by a single pulse.
4. When [symbol] , the DAC will either move toward the ground state, or stay in the same state.

Another example is time interval 204b of FIG. 2A where a first peak is negative, and a peak current Iₚₑₐₖ is peak current 208. Behaviour of the superconducting integrated circuit in this example can be analogous to the behaviour described in the previous example above.

A repetition of time intervals each with a respective power level starting at I_{MAX} and decreasing by Δ_{PWR}< [symbol] /2 can reset a population of DACs with different asymmetries.

In practice, I_{MAX} is generally larger than the largest asymmetry current on the chip, or at least larger than the asymmetry current of the DACs on the chip in the set of DACs to be reset.

To reset a DAC, each value of current I_{PWR} applied to the CJJ loop of the DAC is followed immediately by a current of −|I_{PWR}|.

Increment Δ_{PWR} can be expressed as follows:

Δ_{PWR}=α×Φ₀/L_{BODY}

In some implementations, it can be desirable to satisfy a constraint that α<0.5.

Once Δ_{PWR} and I_{MAX} have been determined, the approach generates a list of N+1 power levels from I_{MAX} to zero as follows:

$$\{ + {I}_{P W R} ( 0 ) , - {I}_{P W R} ( 0 ) , + {I}_{P W R} ( 1 ) , - {I}_{P W R} ( 1 ) , \\ … + {I}_{PWR} ( N - 1 ) , - {I}_{PWR} ( N - 1 ) , + {I}_{PWR} ( N ) , - {I}_{PWR} ( N ) , 0. \}$$

where where I_{PWR}(0)=I_{MAX}, I_{PWR}(N)=I_{PWR}(N−1)−Δ_{PWR}, and I_{PWR}(N)=Δ_{PWR}.

The length of the list can depend on the value of I_{MAX} and Δ_{PWR}, and the time taken to reset the DACs on the chip can depend on the length of the list. A longer list generally results in a longer time taken to reset the DACs. It can be beneficial to generate the shortest list needed to recover the largest number of DACs.

In some implementations, to reduce the total time required to reset all the DACs, a trade-off can be performed between the length of the list of power levels and the number of DACs that can be reset. In this case the DACs with asymmetry larger than I_{MAX} can be individually reset (recovered) by crafting an appropriate sequence of pulses.

One approach is to generate a list of power currents based on room-temperature measurements, and refine the list using low-temperature measurements.

FIG. 3C is a flow chart of an example implementation of a method 300c for resetting a set of DACs in a superconducting integrated circuit, according to the present disclosure. Method 300c includes acts 354 to 372, though those of skill in the art will appreciate that, in alternative implementations, certain acts may be omitted and/or additional acts may be added. Those of skill in the art will appreciate that the illustrated order of the acts is shown for exemplary purposes only and may change in alterative implementations.

At 354, method 300c is invoked. In some implementations, method 300c is invoked once the superconducting integrated circuit has been cooled to temperatures at which its elements are superconducting, readout circuitry is operational, and the superconducting integrated circuit is ready for calibration.

At 356, the system determines a level of junction asymmetry γ based on an estimate of asymmetries between critical currents of Josephson junctions of pairs of Josephson junctions in CJJs of the set of DACs. In some implementations, the estimate is an estimate of the worst-case (i.e., largest or upper limit) asymmetry. Room-temperature measurements can be used to determine the level of junction asymmetry γ. The worst-case junction asymmetry γ on a chip can be estimated by a) measuring a variation (e.g., a standard deviation) of the critical current, at room temperature, of a Josephson junction (or a Josephson junction test structure) in, or close to, the superconducting integrated circuit, and then b) estimating a worst-case junction asymmetry. In some implementations, estimating a worst-case asymmetry includes multiplying the standard deviation by six. In some implementations, owing to on-chip variability, values of junction asymmetry can be in a range −0.15<γ<0.15.

At 358, the system estimates an average critical current Í_{C} of the set of DACs which corresponds to the sum of the critical currents of the two junctions in CJJ 106. Room-temperature measurements can be used to estimate the average critical current. The minimum current on the power line needed to reset the set of DACs can be expressed as I_{PWR}>4 [symbol] γₘₐₓ∨Í_{C}.

At 360, the system measures parameters that characterize a subset of the DACs. In some implementations, the subset of the DACs includes DACs having at least the larger body inductance. The body inductance of DACs is generally known by design. Parameters can include circulating bit weight [symbol] , DAC critical current, a mutual inductance between element the analog line (i.e., the ADDR and/or TRIG line) and CJJ 106. The DAC critical current can be used to refine the estimate of average critical current obtained at 358.

At 362, the system generates a list of power levels I_{PWR}. The positive power levels start at I_{MAX} and decrease in increments to zero. The negative power levels start at −I_{PWR} and increase in increments to zero. An example of a list of power levels is as follows:

{+0.45, −0.45, +0.3, −0.3, +0.15, −0.15, 0.0}

At 364, the system applies a CJJ reset pulse at a first power level to reset one or more DACs of the set of DACs on the chip. At 366, the system determines if there is another power level. If there is another power level (“YES”), then the method returns control to 364 where the system applies another CJJ reset pulse at the next power level.

If reset pulses have been applied for all power levels, and there is no next power level (“NO”), the method proceeds to 368 where the system tests for reset errors. At 370, the system determines if there are reset errors. If reset errors are detected, the procedure can be repeated for a higher value of I_{MAX}. It may take one or more iterations until no reset errors are detected. If reset errors are detected (“YES”), the method returns control to 362 where the system generates another list of power levels. If no reset errors are detected (“NO”), the method proceeds to 372 where the method ends.

Benefits of the technology described in the present application can include the following. Stages belonging to DACs in the set of DACs being reset can be initialized to the same state, thereby eliminating or at least reducing an error in initialization of the DACs. Each DAC in the set of DACs being reset can be initialized to the respective true ground state of the DAC, i.e., the state corresponding to the global minimum of the potential energy of the DAC.

### Distributed Annealing Reset

A superconducting circuit may include one or more multi-stage DACs. In one implementation, the multi-stage DACs are four-stage DACs. Each stage of a multi-stage DAC can be controlled by a combination of a respective power line (PWR) and a respective pair of addressing lines (ADDR and TRIG). The four stages of a four-stage DAC can be controlled by the same PWR line. In some implementations, one pair of addressing lines (ADDR and TRIG) can control the higher two stages of the four-stage DAC, and another pair of addressing lines (ADDR and TRIG) can control the lower two stages. In other implementations, one of the addressing lines (ADDR or TRIG) controlling the higher two stages of the four-stage DAC can also be used to control the lower two stages.

The superconducting circuit may be a quantum processor, or a portion of a quantum processor, for example.

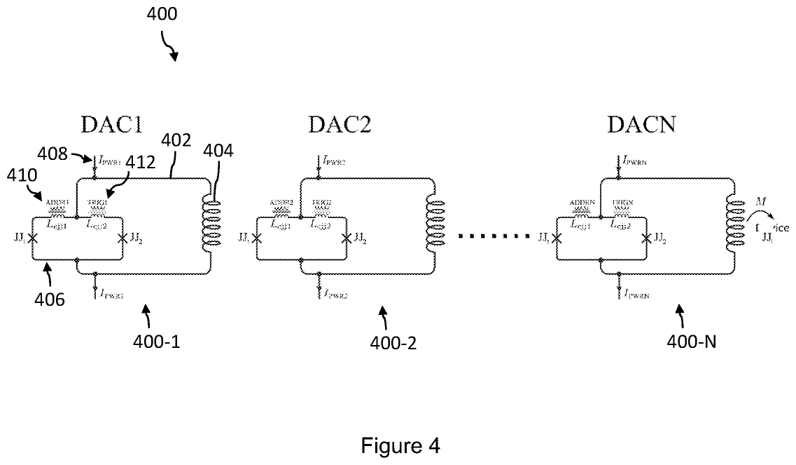

FIG. 4 is a schematic diagram of an example implementation of a DAC array 400, according to the present disclosure (also referred to herein as a DAC plaquette). DAC array 400 includes N DACs 400-1, 400-2, . . . 400-N, where N≥2. DAC array 400 of the example implementation of FIG. 4 includes at least 3 DACs. If N=3, DAC array 400 includes 3 DACs.

Each DAC of DAC array 400 can be a superconducting DAC, for example, superconducting DAC 100 of FIG. 1. For example, DAC 400-1 includes superconducting loop 402, inductance 404, and CJJ 406.

Each DAC of DAC array 400 can be controlled by a combination of a respective power line and a respective pair of addressing lines. For example DAC 400-1 can be controlled by power line 408 (PWR1) and addressing lines 410 (ADDR1) and 412 (TRIG1). It will be understood that in other implementations each DAC may be controlled by a power line and a single addressing line or by a power line and a plurality of addressing lines. In some implementations the power line may be shared between multiple DACs, and the single addressing line or the plurality of addressing lines may be shared between multiple DACs.

Each DAC of DAC array 400 can be a multi-stable radio-frequency superconducting quantum interference device (RF-SQUID) whose metastable states can correspond to integer numbers of flux quanta stored in a body of the RF-SQUID (e.g., loop 102 of superconducting DAC 100 of FIG. 1). A superconducting DAC is also referred to in the present application as a flux storage device and programmable magnetic memory. During programming, a state of the DAC can be adjusted by an integer number of flux quanta, either positive or negative in polarity, up to a predetermined maximum single flux quanta (SFQ).

The RF-SQUID can also be reset to a zero state. The zero state can be a ground state. Programming a DAC to a desired state usually starts from the zero state. The zero state can be achieved by a reset procedure. The DAC can be reset from a known or an unknown state.

One approach to resetting a DAC includes setting the power line (PWR) to zero, and applying pulses on the addressing lines (ADDR and TRIG) with large enough amplitude to reliably drive transitions that “de-program” the DAC one SFQ at a time until the DAC reaches its lowest-energy zero SFQ state for which the circulating current is zero. During the procedure, DACs communicatively 780 coupled to the same addressing lines can receive the same signal, and can be reset simultaneously.

In some implementations, a number of DACs are reset by activating the power lines and the addressing lines communicatively coupled to the DACs and causing a sequence of pulses to be applied simultaneously to the DACs. In some implementations, resetting the DACs can include applying a sequence of pulses at different power levels. Applying a sequence of pulses at different power levels can increase the number of pulses applied during the resetting of the DACs.

Resetting the DACs can include applying a sequence of pulses that exceed a critical current of the DACs which can cause the DAC to transition from a superconducting state to a normal (non-superconducting) state. Repeated transitions between a superconducting state and a normal state can cause an increase in a temperature of the superconducting integrated circuit. An increase in temperature of the superconducting integrated circuit can affect performance of the superconducting integrated circuit, for example, during calibration and/or operation.

One approach to mitigate the effect of the increase in temperature is to wait for a time at least sufficient for the superconducting integrated circuit to dissipate heat caused by the repeated transitions between superconducting and normal states, and for the superconducting integrated circuit to return to a base temperature. The base temperature is an operational temperature of the superconducting integrated circuit prior to the resetting of the DACs. In practice, the waiting time can be on the order of several seconds.

It can be beneficial to eliminate or at least reduce the waiting time. A delay of several seconds can adversely affect calibration and/or problem-solving. For example, in the case of a quantum processor, a delay caused by resetting the DACs can increase a time taken for the quantum processor to return a result.

The present disclosure describes systems and methods for partitioning addressing lines into two or more groups, and resetting DACs communicatively coupled to the addressing lines belonging to each group simultaneously. These systems and methods are also referred to in the present application as a distributed annealing reset.

Groups may be reset sequentially and/or simultaneously. The number of groups may be selected based at least in part on a) a desired duration for the reset procedure, and b) an acceptable value for the peak temperature reached by the superconducting integrated circuit during the reset procedure.

In some implementations, the desired duration is less than a predetermined duration threshold. In some implementations, the acceptable value for the peak temperature is a temperature below a predetermined temperature threshold.

Multiple DACs can be reset simultaneously by activating the addressing lines belonging to a group of DACs. DACs communicatively coupled to addressing lines in groups other than the group being activated can remain in their current state, i.e., the number of flux quanta stored in the body of those DACs can remain unchanged.

One approach to performing a distributed annealing reset is to a) select a subset of addressing lines and use an annealing power sequence (e.g., the annealing power sequence described above) to reset a group of DACs communicatively coupled to the subset of addressing lines to their zero state, and then b) repeat for other subsets of addressing lines to reset other groups of DACs.

Another approach is to a) define a sequence of annealing power levels, b) for a first power level, apply a sequence of pulses to each group of DACs in turn, and c) repeat for each power level.

Groups of DACs can be selected to satisfy a number of criteria. For example, groups can be selected such that the average number of DACs addressed simultaneously is at least approximately the same, i.e., the average number of DACs addressed simultaneously varies within a predetermined tolerance. In one implementation, the average number of DACs addressed simultaneously varies within a tolerance of 10%. In another implementation, the average number of DACs addressed simultaneously varies within a tolerance such that a standard deviation in the number of DACs addressed simultaneously is 25% of the average number of DACs addressed simultaneously.

In another example, groups of DACs are selected such that the constituent DACs of each group are similarly at least approximately uniformly distributed across the superconducting integrated circuit.

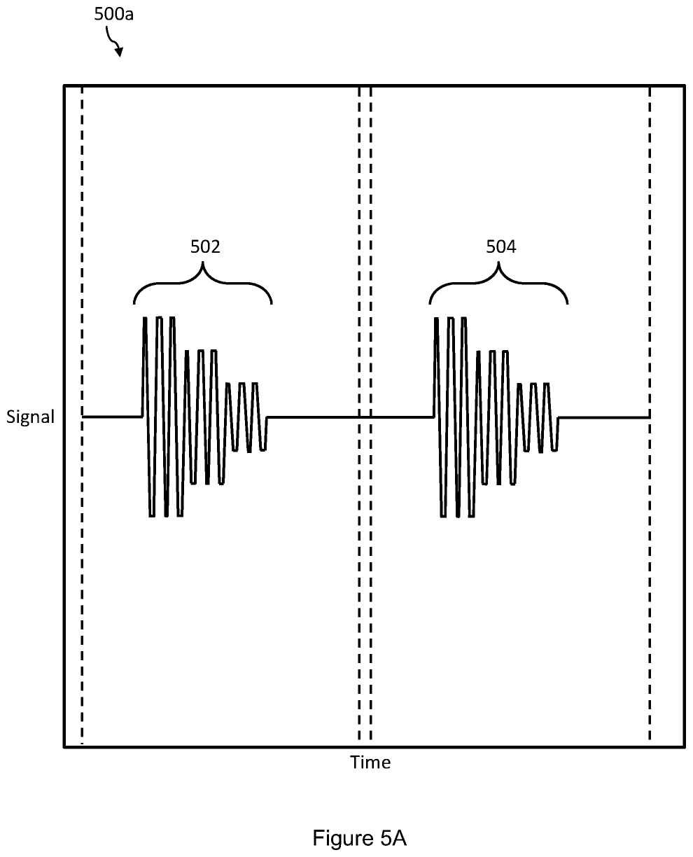

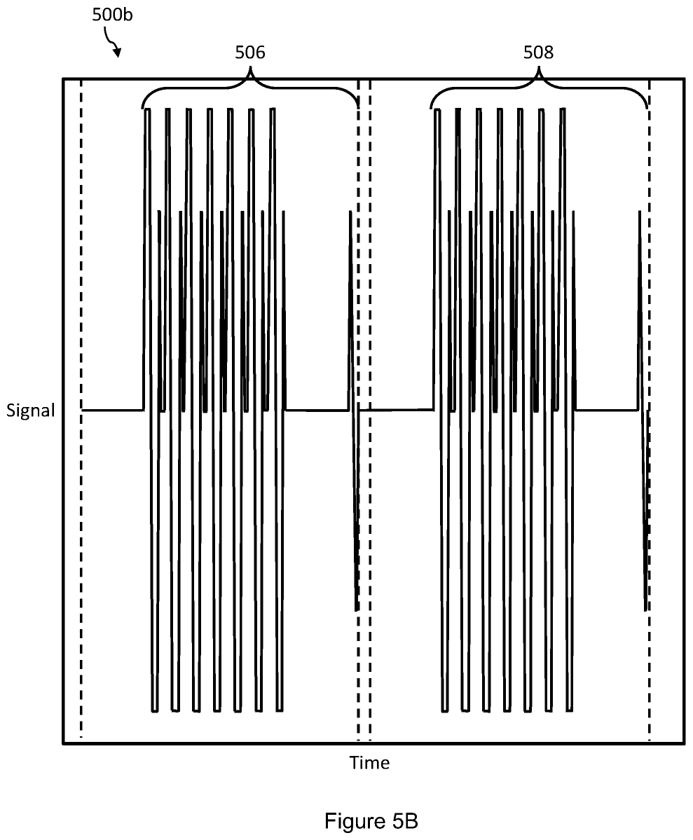

FIG. 5A is a plot 500a of example time-dependent signals 502 and 504 applied to respective power lines of each DAC of a pair of DACs, according to the present disclosure. Each DAC of the pair of DACs may be a superconducting DAC, e.g., the superconducting DAC of FIG. 1.

FIG. 5B is a plot 500b of an example time-dependent signals 506 and 508 applied to respective CJJ loops of each DAC of the same pair of DACs referred to in FIG. 5B, according to the present disclosure.

In an example implementation of a superconducting integrated circuit that includes a superconducting quantum processor (referred to as a P16 processor), systems and methods described in the present application can control 86,736 four-stage DACs with 128 power channels and 57 addressing channels. In another example implementation of a superconducting integrated circuit that includes a superconducting quantum processor (referred to as a P6 processor), systems and methods described in the present application can control 10,296 four-stage DACs with 29 power channels and 61 addressing channels.

In FIGS. 5A and 5B, signals cause DAC1 and DAC2 to reset at different times even if the two DACs have a common addressing line. The process is essentially equivalent to resetting DAC1 using the protocol described above with references to FIGS. 2A, 2B, 3A, 3B, and 3C on DAC1, and then resetting DAC2.

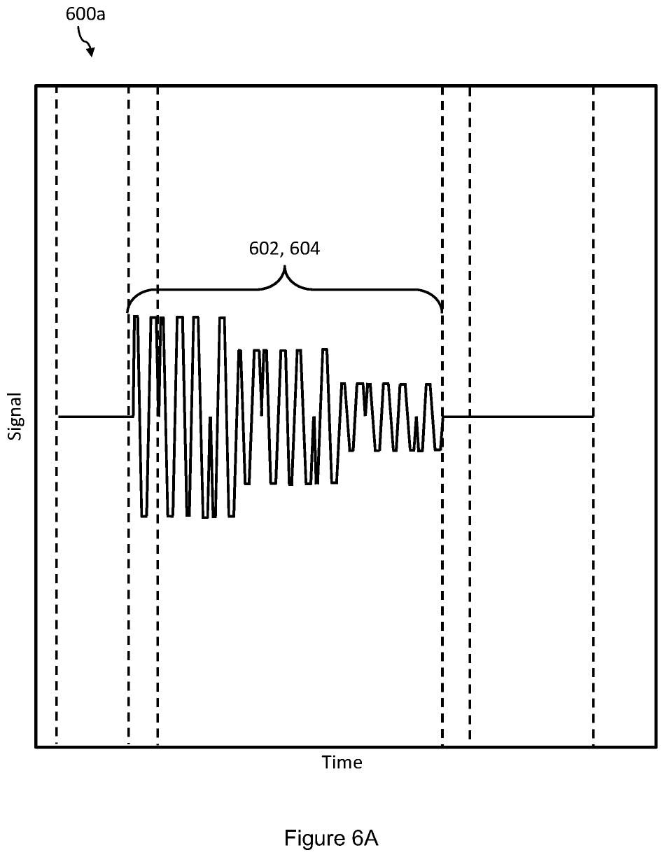

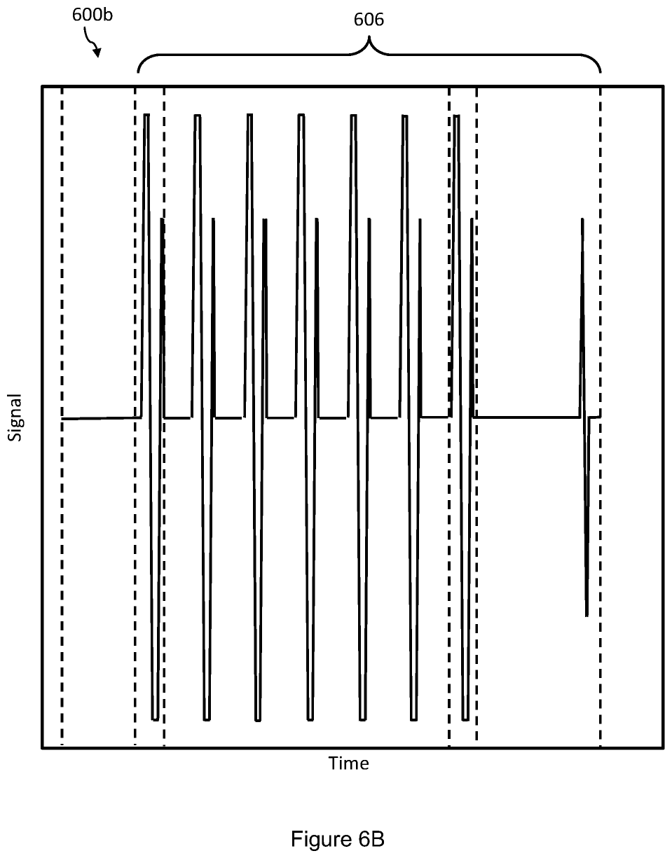

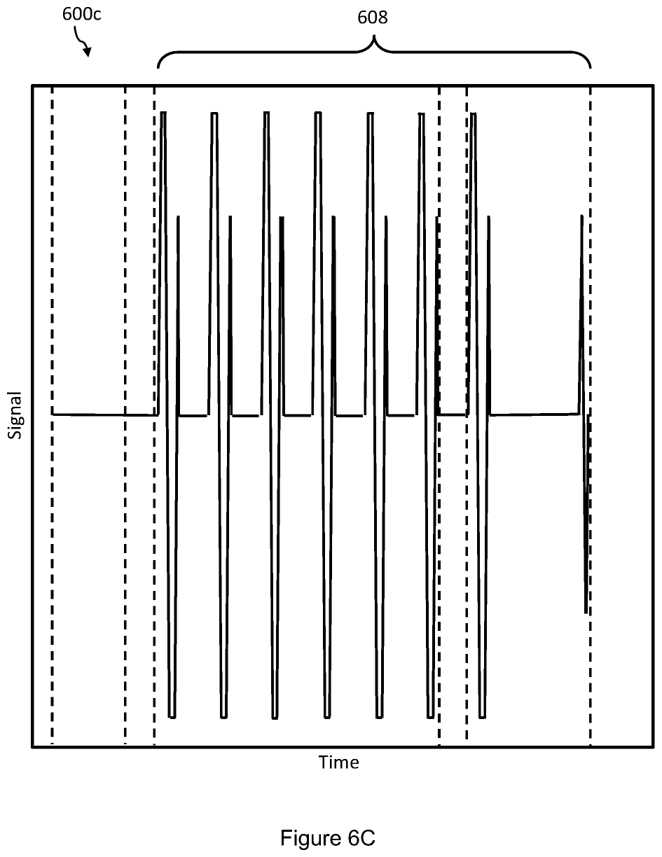

FIG. 6A is a plot 600a of example time-dependent signals 602 and 604 applied to respective power lines of each DAC of a pair of DACs (DAC1 and DAC2), according to the present disclosure. Signals 602 and 604 can be applied to power lines of DAC1 and DAC2 at each of a number of power levels. Signals 602 and 604 may be applied sequentially. Signals 602 and 604 may be the same as each other. Signals 602 and 604 may be overlapping.

FIG. 6B is a plot 600b of an example time-dependent signal 606 applied to a CJJ loop of a first DAC (DAC1) of the same pair of DACs referred to in FIG. 6A, according to the present disclosure.

FIG. 6C is a plot 600c of an example time-dependent signal 608 applied to a CJJ loop of a second DAC (DAC2) of the same pair of DACs referred to in FIGS. 6A and 6B, according to the present disclosure.

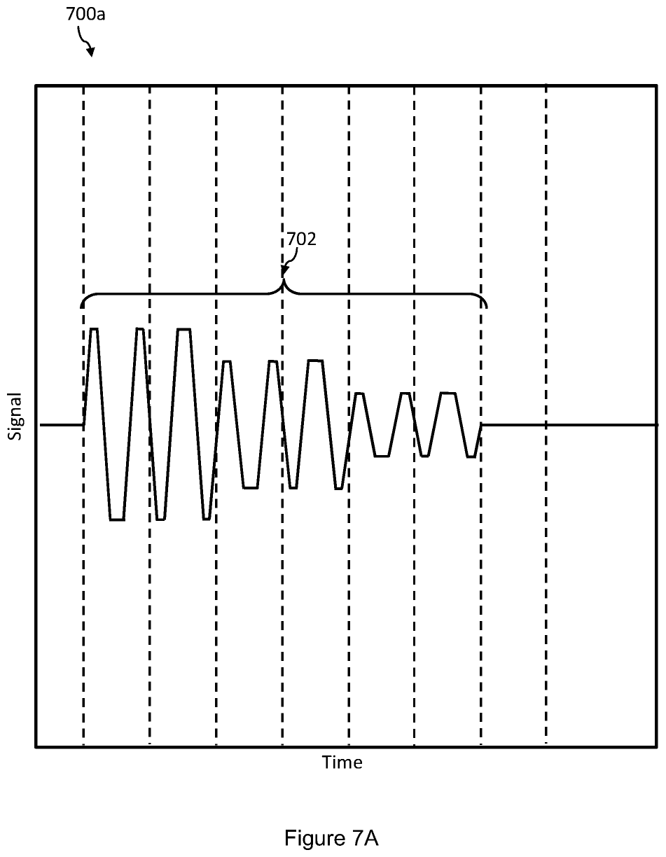

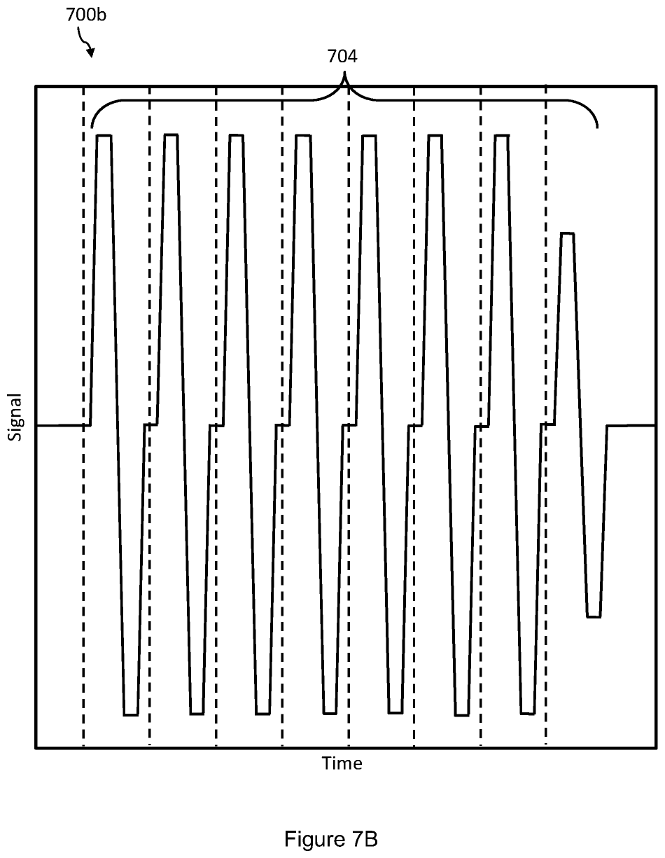

FIG. 7A is a plot 700a of an example time-dependent signal 702 applied to a power line of a DAC, according to the present disclosure. Signal 702 is a current applied to a body of the DAC.

FIG. 7B is a plot 700b of an example time-dependent signal 704 applied to a CJJ loop of the same DAC referred to in FIG. 7A, according to the present disclosure. Signal 704 is a magnetic flux applied to the CJJ loop.

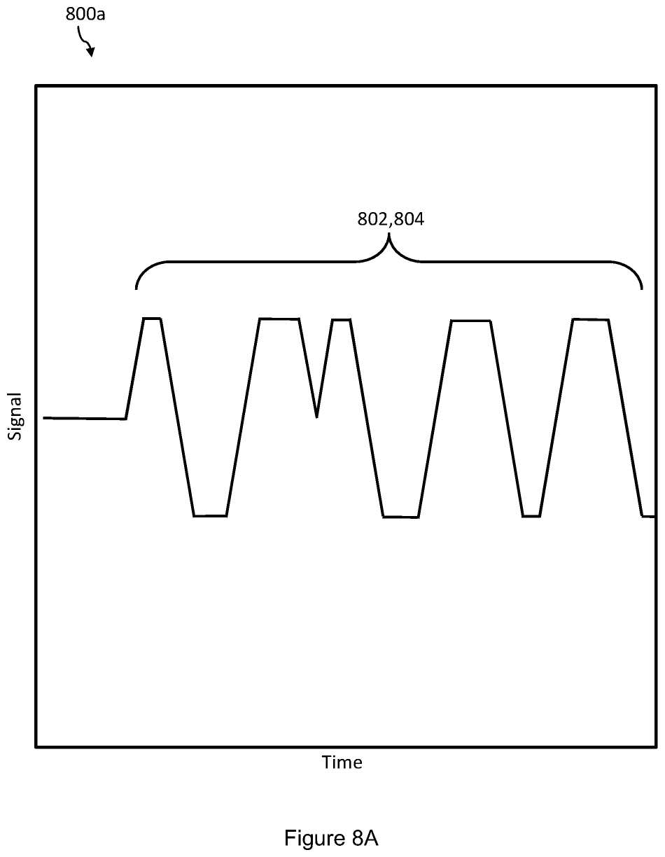

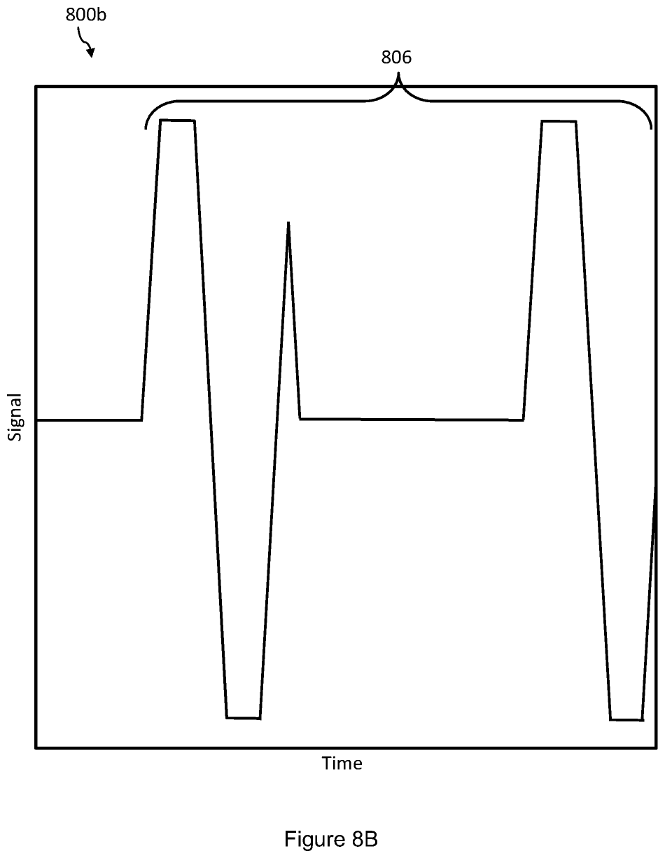

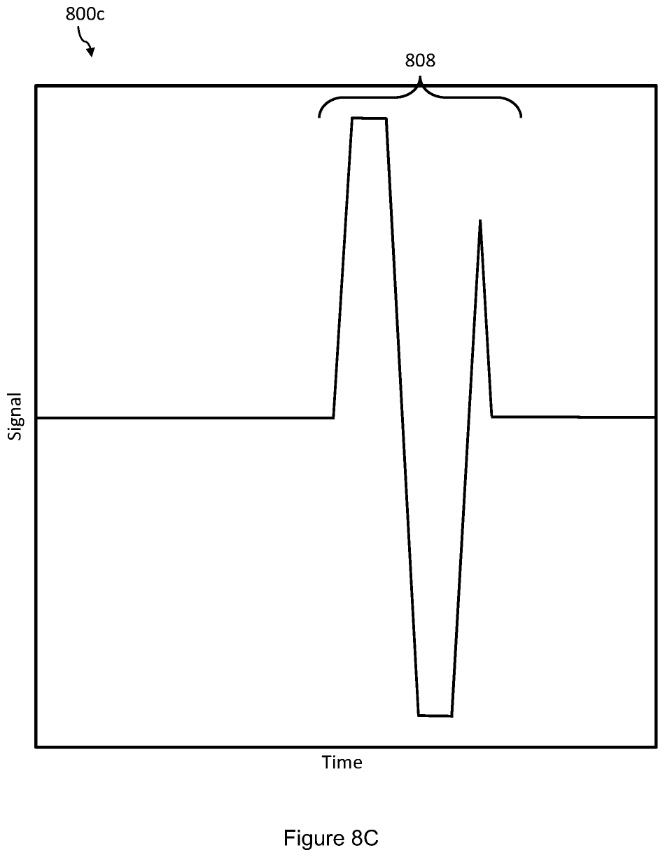

FIG. 8A is a plot 800a of example time-dependent signals 802 and 804 applied to respective power lines of each DAC (DAC1 and DAC2) of a pair of DACs, according to the present disclosure.

FIG. 8B is a plot 800b of an example time-dependent signal 806 applied to addressing lines (ADDR and TRIG) of DAC1 of FIG. 8A, according to the present disclosure.

FIG. 8C is a plot 800c of an example time-dependent signal 808 applied to addressing lines (ADDR and TRIG) of DAC2 of FIG. 8A, according to the present disclosure.

Assuming a DAC can only be activated by an additive combination of signals in a pair of addressing lines, the number of DACs N_{DAC} addressable by activating pairs of addressing lines selected from a number l addressing lines can be expressed as follows:

N_{DAC}=l!/[2×(l−2)!]

For example, fifteen (15) DACs can be addressed by activating pairs of addressing lines selected from six (6) addressing lines (l=6, N_{DAC}=15 [symbol] .

In practice, two DACs can share the same pair of addressing lines if one of the two DACs is activated by an additive combination of signals on the lines, and the other DAC is activated by a subtractive combination of signals on the lines, for example, additive combination (+1,+1) and subtractive combination (+1,−1).

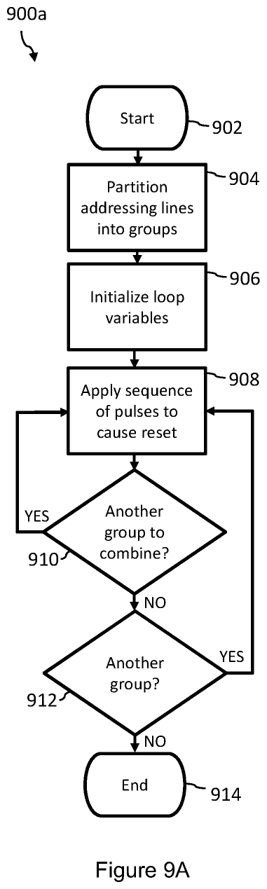

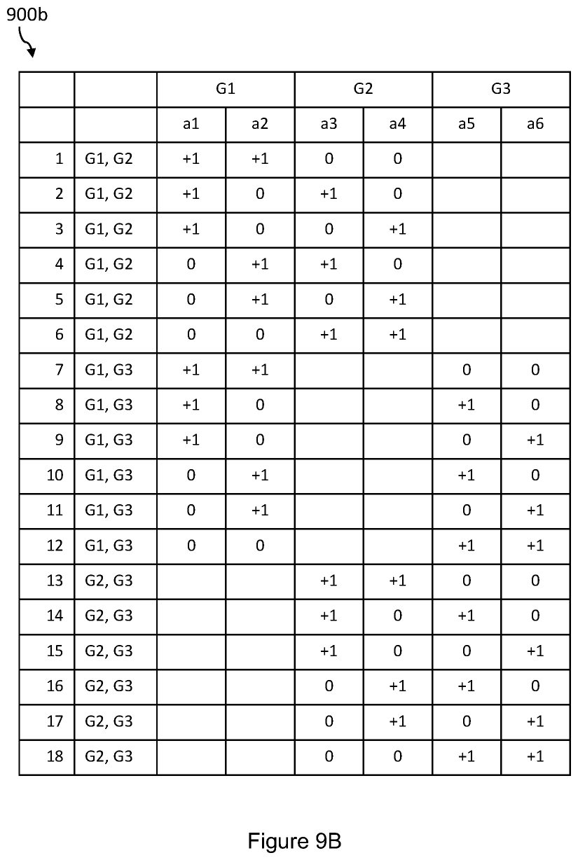

FIG. 9A is a flowchart 900a of an example method for resetting a set of DACs in a superconducting integrated circuit, according to the present disclosure. The method for performing a distributed annealing reset illustrated in FIG. 9A includes the following:
partitioning the addressing lines into N_{G} groups G1, G2, . . . GN_{G}, each group being of size m/2;
for i=1 [symbol] N_{G}
   for j=i+1 [symbol] N_{G}
      combining groups Gi and Gj; and
      applying a sequence of pulses to cause addressable DACs communicatively coupled to addressing lines in groups Gi and Gj to reset.

In one implementation, partitioning the addressing lines into groups can include a) determining an even number m of addressing lines that can be activated at the same time without causing a temperature of the chip to increase above a predetermined threshold, and b) dividing the addressing lines into groups of size m/2.

The technology described in the present application including the method described in FIG. 9A can advantageously reduce heating of the chip during a reset procedure. For example, it can advantageously reduce heating of qubits and other superconducting devices in a superconducting quantum processor during a reset procedure. In some implementations, the temperature of the chip after reset is non-linearly related to the number of groups. For example, doubling the number of groups can more than halve the increase in temperature.

Method 900a includes acts 902 to 914, though those of skill in the art will appreciate that, in alternative implementations, certain acts may be omitted and/or additional acts may be added. Those of skill in the art will appreciate that the illustrated order of the acts is shown for exemplary purposes only and may change in alterative implementations.

At 902, method 900a is invoked. In some implementations, method 900a is invoked once the superconducting integrated circuit has been cooled to temperatures at which its elements are superconducting, readout circuitry is operational, and the superconducting integrated circuit is ready for calibration.

At 904, the system partitions addressing lines into groups. The system can partition addressing lines into groups as described above. For example, groups may be selected based at least in part on a) a desired duration for the reset procedure, and/or b) an acceptable value for the peak temperature reached by the superconducting integrated circuit during the reset procedure. In another example, groups can be selected such that DACs reset by activating lines of each group are at least approximately uniformly distributed across the superconducting integrated circuit.

At 906, the system initializes the loop variables. Initializing the loop variables can include initializing i=1 and j=i+1 in the above description. At 908, the system applies a sequence of pulses to reset a subset of DACs. The subset of DACs can be DACs activated by addressing lines belonging to one or more groups of addressing lines. The sequence of pulses can be selected to cause addressable DACs communicatively coupled to addressing lines in groups Gi and Gj to reset. FIG. 900b (below) illustrates an example pulse sequence.

At 910, the system determines if there are more groups to be combined. If so, method 900a returns to 908, and applies another sequence of pulses to reset another subset of DACs. If no more groups to be combined, then method 900a proceeds to 912 where the system determines if there is another group. If so, method 900a returns to 908. If the system determines there are no more groups, the method proceeds to 914 where the method ends.

FIG. 9B is a table 900b of an example pulse sequence for the distributed annealing reset procedure of FIG. 9A, according to the present disclosure.

Table 900b includes six (6) addressing lines, a1, a2, a3, a4, a5, and a6, arranged in three groups, G1, G2, and G3. Group G1 consists of addressing lines a1 and a2. Group G2 consists of addressing lines a3 and a4. Group G3 consists of addressing lines a5 and a6. Two (2) addressing lines of addressing lines a1, a2, a3, a4, a5, and a6 can be activated to reset each DAC.

Each row in table 900b corresponds to a combination of two activated addressing lines. For example, row 1 corresponds to a combination of activated addressing lines a1 and a2. Activation of each addressing line is indicated in table 900 by a “1” in the respective column. Each addressing line that has not been activated is indicated in table 900 by a “0” in the respective column.

A blank indicates that those line are not activated (effectively a “0”) and is used to aid in the identification of the groups.

Table 900b shows a pairwise combination of groups. For example, in rows 1-6 of table 900b, groups G1 and G2 are reset at the same time. For each row (i.e., for each combination of activated addressing lines), the distributed annealing reset procedure causes a sequence of pulses to be applied to the addressable DACs. The addressable DACs are the DACs communicatively coupled to the activated addressing lines. The sequence of pulses applied to the addressable DACs causes the addressable DACs to be reset.

In rows 7-12 of table 900b, groups G2 and G3 are reset at the same time, and, in rows 13-18 of table 900b, groups G1 and G3 are reset at the same time.

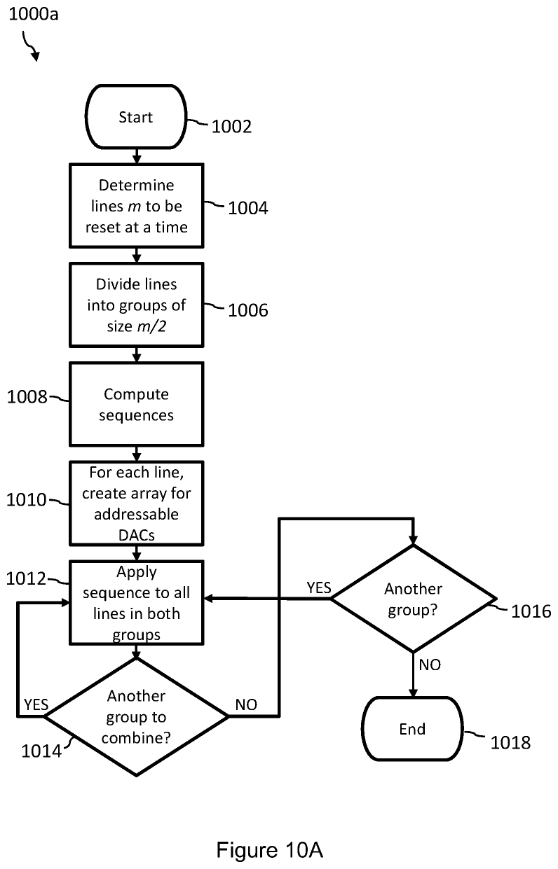

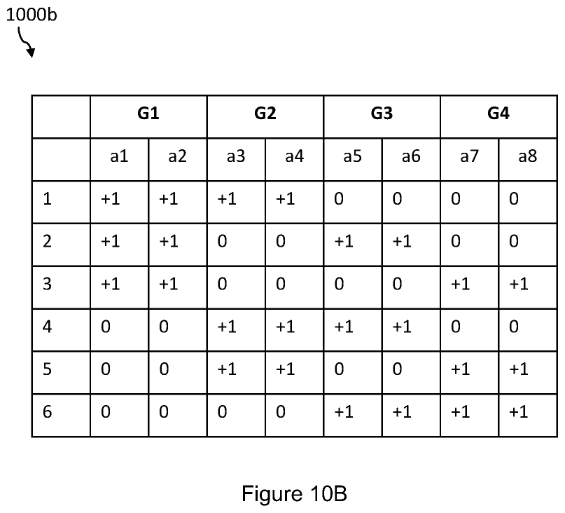

FIG. 10A is a flowchart of another example method 1000a for resetting a set of DACs in a superconducting integrated circuit, according to the present disclosure. The method 1000a for performing a distributed annealing reset illustrated in FIG. 10A includes the following:
Determining an even number of addressing lines m that can be activated at the same time without causing a temperature of the chip to increase above a predetermined temperature threshold.
Dividing the addressing lines into a number N_{G} of groups, each group of size m/2 addressing lines.
Computing sequences that allow addressing of each DAC addressable in each group (or when lines can be combined, to address all the DACs addressable by the combination of lines).
For each addressing line, creating an array of size equal to the total number of DACs addressable, which can be expressed as follows for an additive combination of signals to the ADDR and TRIG lines:
   N_{DAC}=l!/[2×(l−2)!] where l is the number of addressing lines.
for i=1 [symbol] N_{G},
   for j=i+1 [symbol] N_{G}
      applying the sequences S to all lines in groups Nᵢ and Nⱼ to cause addressable DACs communicatively coupled to addressing lines Ai and Aj to reset.

Method 1000a includes acts 1002 to 1018, though those of skill in the art will appreciate that, in alternative implementations, certain acts may be omitted and/or additional acts may be added. Those of skill in the art will appreciate that the illustrated order of the acts is shown for exemplary purposes only and may change in alterative implementations.

At 1002, method 1000a is invoked. In some implementations, method 1000a is invoked once the superconducting integrated circuit has been cooled to temperatures at which its elements are superconducting, readout circuitry is operational, and the superconducting integrated circuit is ready for calibration.

At 1004, the system determines the number m of lines to be activated at one time. At 1006, the system divides the lines into groups of size m/2. In other implementations, the system divides the lines into groups of other sizes e.g., m/3 or m/4. At 1008, the system computes a sequence of pulses to reset a subset of DACs. Partitioning lines into groups and computing a sequence of pulses are described above with reference to Figure 900a. Figure 1000b illustrates an example pulse sequence.

At 1010, the system creates an array for addressable DACs. At 1012, the system applies a sequence to lines in a combination of groups, e.g., a combination of two groups (also referred to in the present application as a pairwise combination). At 1014, the system determines if there is another group to combine. If so, method 1000a returns to 1012, and applies another sequence of pulses to reset another subset of DACs. If there are no more groups to be combined, then method 1000a proceeds to 1016 where the system determines if there is another group. If so, method 1000a returns to 1012. If the system determines there are no more groups, the method proceeds to 1018 where the method ends.

FIG. 10B is a table 1000b of an example pulse sequence for the distributed annealing reset procedure of FIG. 10A, according to the present disclosure.

Table 1000b includes eight (8) addressing lines, a1, a2, a3, a4, a5, a6, a7, and a8, arranged in four groups, G1, G2, G3, and G4. Group G1 consists of addressing lines a1 and a2. Group G2 consists of addressing lines a3 and a4. Group G3 consists of addressing lines a5 and a6. Group G4 consists of addressing lines a7 and a8. Two (2) addressing lines of addressing lines a1, a2, a3, a4, a5, a6, a7, and a8 can be activated to reset each DAC.

Table 1000b is populated as follows. In each group of the example illustrated in table 1000b, the only available sequence is (+1,+1). First, group 1 is combined with group 2 to give a first sequence where lines a1 through a4 are +1, and the remainder are 0. Second, group 1 is combined with group 3 to give a second sequence where lines a1, a2, a5, and a6 are +1 and the remainder are 0. Third, group 1 is combined with group 4 to give a third sequence where lines a1, a2, a7, and a8 are +1 and the remainder are 0.

Fourth, group 2 is combined with group 3 to give a fourth sequence where lines a3 through a6 are +1 and the remainder are 0. Fifth, group 2 is combined with group 4 to give a fifth sequence where lines a3, a4, a7, and a8 are +1 and the remainder are 0. Sixth, group 3 is combined with group 4 to give a sixth sequence where lines a5 through a8 are +1 and the remainder are 0.

In general, method 1000a of FIG. 10A can be more efficient than method 900a of FIG. 9A, and a total number of reset pulses used in method 1000a can be less than or equal than to a total number of reset pulses used in method 900a.

In an example scenario of a circuit having 60 addressing lines in which it is desirable for at least the reasons described above to activate only 20 lines at one time, the lines are divided into groups of 10 lines. There are 6 groups, and each group can be activated with each other in a total of 15 sequences.

If the lines are labeled (in no particular order) L1 through L60, and grouped by number, then the 6 groups are L1-L10, L11-L20, L21-L30, L31-40, L41-50, and L51-60. Sequences able to reset DACs can be activated for lines in each pair of groups as follows:
L1-10 L11-20, L1-10 L21-30, L1-10 L31-40, L1-10 L41-50, L1-10 L51-60,
L11-20 L21-30, L11-20 L31-40, L11-20 L41-50, L11-20, L51-60,
L21-30 L31-40, L21-30 L41-50, L21-30 L51-60,
L31-L40 L41-L50, L31-40 L51-L60,
L41-50 L51-60.

In another scenario, also having 60 addressing lines but where only 15 can be activated at one time, 12 groups of 5 lines each can be formed. Sequences able to reset the DACs can be generated for various combinations of 3 groups.

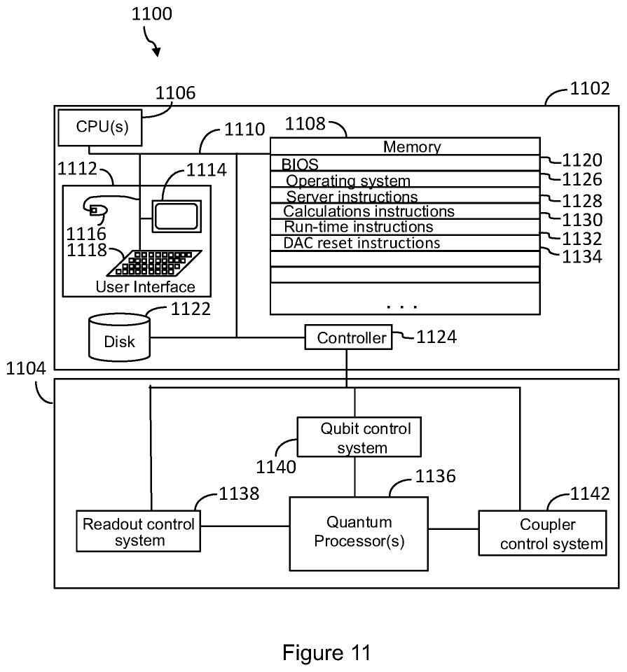

FIG. 11 shows a hybrid computing system 1100 according to at least one exemplary implementation, including a digital computer 1102 and a quantum computer 1104, that may incorporate systems and methods described in the present application, including flux storage device e.g., DACs.

Digital computer 1102 comprises CPU 1106, user interface elements 1108, 1110, 1112 and 1114, disk 1116, controller 1118, bus 1120 and memory 1122. Memory 1122 comprises modules 1124, 1126, 1128, 1130, 1132, and 1134. Module 1134 includes DAC reset instructions which may be used to cause resetting of one or more DACs e.g., by methods described in the present application.

Quantum computer 1104 can incorporate one or more flux storage devices e.g., DAC 100 of FIG. 1 and/or DAC array 400 of FIG. 4. Quantum computer 1104 comprises quantum processor 1136, readout control system 1138, qubit control system 1140 and coupler control system 1142.

The various embodiments described above can be combined to provide further embodiments. To the extent that they are not inconsistent with the specific teachings and definitions herein, all of the U.S. patents, U.S. patent application publications, U.S. patent applications, foreign patents, and foreign patent applications referred to in this specification and/or listed in the Application Data Sheet that are assigned to the assignee of this patent application, including but not limited to the following: International patent application publication WO2019222514A1, SYSTEMS AND METHODS FOR ADDRESSING DEVICES IN A SUPERCONDUCTING CIRCUIT, filed May 16, 2019; U.S. Pat. No. 10,528,886; United States Patent Application Publication No. 2021/0190885; U.S. patent application Ser. No. 16/996,595, SYSTEMS AND METHODS FOR ADDRESSING DEVICES IN A SUPERCONDUCTING CIRCUIT, filed Aug. 19, 2019, and U.S. Patent Application No. 63/128,416, SYSTEMS AND METHODS FOR CONTROLLING DEVICES IN A SUPERCONDUCTING CIRCUIT, filed Dec. 21, 2021, are incorporated herein by reference, in their entireties. Aspects of the embodiments can be modified, if necessary, to employ systems, circuits and concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of operation of a system, the system comprising a superconducting integrated circuit and a controller, the superconducting integrated circuit comprising a plurality of flux storage devices, each of the plurality of flux storage devices comprising a superconducting loop interrupted by a respective compound Josephson junction, the respective compound Josephson junction comprising a respective pair of Josephson junctions, each of the plurality of flux storage devices communicatively coupled to a respective one of a plurality of addressing lines and to a respective one of a plurality of power lines, the method being performed by the controller, the method comprising:
estimating a worst-case asymmetry between Josephson junctions of the respective pair of Josephson junctions for the plurality of flux storage devices;
estimating an average critical current for the plurality of flux storage devices;
determining a starting level for current on the respective one of a plurality of power lines of each of the plurality of flux storage devices, the starting level based at least in part on the worst-case asymmetry and the average critical current;
determining a power level increment;
generating a sequence of discrete power levels, the sequence which includes:
positive power levels between the starting level and zero, the positive power levels decrementing by the power level increment; and
negative power levels between an additive inverse of the starting level and zero, the negative power levels incrementing by the power level increment, the positive and the negative power levels being alternating in the generated sequence of discrete power levels; and
applying, for each power level of the sequence of discrete power levels, one or more pulses via the respective one of a plurality of addressing lines to the respective compound Josephson junction of each of the plurality of flux storage devices to cause each of the plurality of flux storage devices to reset.

2. The method of claim 1, further comprising:
testing the superconducting integrated circuit for reset errors; and
if reset errors are detected, updating the starting level.

3. The method of claim 1, wherein the estimating a worst-case asymmetry between Josephson junctions of the respective pair of Josephson junctions for the plurality of flux storage devices includes determining a variation of a respective critical current of each of one or more Josephson junctions in or adjacent to the superconducting integrated circuit.

4. The method of claim 3, wherein the determining a variation of the respective critical current of each of one or more Josephson junctions in or adjacent to the superconducting integrated circuit includes determining the variation of the respective critical current of each of one or more Josephson junctions in or adjacent to the superconducting integrated circuit at room temperature.

5. The method of claim 1, wherein the applying, for each power level of the sequence of discrete power levels, one or more pulses via the respective one of a plurality of addressing lines to the respective compound Josephson junction of each of the plurality of flux storage devices includes applying one or more pulses via a pair of addressing lines to the respective compound Josephson junction of each of the plurality of flux storage devices simultaneously.

6. The method of claim 1, wherein the applying, for each power level of the sequence of discrete power levels, one or more pulses via the respective one of a plurality of addressing lines to the respective compound Josephson junction of each of the plurality of flux storage devices to cause each of the plurality of flux storage devices to reset includes applying, for each power level of the sequence of discrete power levels, one or more pulses via the respective one of a plurality of addressing lines to the respective compound Josephson junction of each of the plurality of flux storage devices to cause a superconducting digital-to-analog converter (DAC) to reset.

7. The method of claim 6, wherein the applying, for each power level of the sequence of discrete power levels, one or more pulses via the respective one of a plurality of addressing lines to the respective compound Josephson junction of each of the plurality of flux storage devices to cause a superconducting DAC to reset includes applying, for each power level of the sequence of discrete power levels, one or more pulses via the respective one of a plurality of addressing lines to the respective compound Josephson junction of each of the plurality of flux storage devices to cause the superconducting DAC to reset, the superconducting DAC which includes a loop of superconducting material interrupted by an inductance, the inductance being at least one of a lumped-element inductance, a distributed inductance, a kinetic inductance, and an intrinsic inductance of the loop of superconducting material.

8. The method of claim 7, wherein the applying, for each power level of the sequence of discrete power levels, one or more pulses via the respective one of a plurality of addressing lines to the respective compound Josephson junction of each of the plurality of flux storage devices to cause a superconducting DAC to reset, the superconducting DAC which includes a loop of superconducting material interrupted by an inductance, includes applying, for each power level of the sequence of discrete power levels, one or more pulses via the respective one of a plurality of addressing lines to the respective compound Josephson junction of each of the plurality of flux storage devices to cause the superconducting DAC to reset, the superconducting DAC being inductively communicatively coupled to a programmable device via at least a portion of the inductance.

9. The method of claim 6, wherein the applying, for each power level of the sequence of discrete power levels, one or more pulses via the respective one of a plurality of addressing lines to the respective compound Josephson junction of each of the plurality of flux storage devices to cause a superconducting DAC to reset includes applying, for each power level of the sequence of discrete power levels, one or more pulses via the respective one of a plurality of addressing lines to the respective compound Josephson junction of each of the plurality of flux storage devices to cause a superconducting DAC to reset, the superconducting DAC being one of a plurality of superconducting DACs, each one of the plurality of superconducting DACs communicatively coupled to a pair of addressing lines of the plurality of addressing lines, the superconducting DAC in operation being addressable by a pair of addressing lines, each addressing lines in the pair of addressing lines being shared with at least one other superconducting DAC.

10. The method of claim 9, wherein determining a starting level for current on the respective one of a plurality of power lines of each of the plurality of flux storage devices comprises determining a starting level for current on the respective one of a plurality of power lines, each power line of the plurality of power lines being shared with at least one other superconducting DAC.

11. The method of claim 1, wherein the applying, for each power level of the sequence of discrete power levels, one or more pulses via the respective one of a plurality of addressing lines to the respective compound Josephson junction of each of the plurality of flux storage devices to cause each of the plurality of flux storage devices to reset includes applying, for each power level of the sequence of discrete power levels, one or more pulses via the respective one of a plurality of addressing lines to the respective compound Josephson junction of each of the plurality of flux storage devices to cause each of the plurality of flux storage devices to reset to a ground state.

12. A method of operation of a system, the system comprising a superconducting integrated circuit and a controller, the superconducting integrated circuit comprising a plurality of flux storage devices, each of the plurality of flux storage devices communicatively coupled to a respective pair of a plurality of addressing lines and to a respective one of a plurality of power lines, the method being performed by the controller, the method comprising:
partitioning the plurality of addressing lines into one or more addressing line groups; and
for each pairwise combination of addressing line groups, applying a respective sequence of pulses to each addressing line of each pairwise combination of addressing line groups to cause one or more of the plurality of flux storage devices to reset.

13. The method of claim 12, wherein the causing a flux storage device of the plurality of flux storage devices to reset includes causing a superconducting digital-to-analog converter (DAC) to reset.

14. The method of claim 13, wherein the causing a superconducting DAC to reset includes causing a superconducting DAC to reset, the superconducting DAC which includes a loop of superconducting material interrupted by an inductance, the inductance being at least one of a lumped-element inductance, a distributed inductance, a kinetic inductance, and an intrinsic inductance of the loop of superconducting material.

15. The method of claim 14, wherein the causing a superconducting DAC to reset, the superconducting DAC which includes a loop of superconducting material interrupted by an inductance, includes causing a superconducting DAC to reset, the superconducting DAC being inductively communicatively coupled to a programmable device via at least a portion of the inductance.

16. The method of claim 12, wherein the causing a superconducting DAC to reset includes causing a superconducting DAC to reset to a ground state.

17. The method claim 12, wherein the partitioning the plurality of addressing lines into one or more addressing line groups includes determining a number m of the plurality of addressing lines to be activated simultaneously, and partitioning the plurality of addressing lines into groups of size m/2.

18. The method of claim 17, wherein the determining a number m of the plurality of addressing lines to be activated simultaneously includes determining a number m of the plurality of addressing lines that can be activated to cause one or more flux storage devices of the plurality of flux storage devices to reset while keeping a temperature of the superconducting integrated circuit below a predetermined temperature threshold.

19. The method of claim 17, wherein the determining a number m of the plurality of addressing lines to be activated simultaneously includes determining a number m of the plurality of addressing lines that can be activated to cause the plurality of flux storage devices to reset within a duration of time less than a predetermined duration threshold.

20. The method of claim 12, wherein the applying a respective sequence of pulses to each addressing line of each pairwise combination of addressing line groups to cause one or more of the plurality of flux storage devices to reset includes applying the respective sequence of pulses to each addressing line of each pairwise combination of addressing line groups sequentially.

21. A method of operation of a system, the system comprising a superconducting integrated circuit and a controller, the superconducting integrated circuit comprising a plurality of flux storage devices, each of the plurality of flux storage devices communicatively coupled to at least one of a plurality of addressing lines and to a respective one of a plurality of power lines, the method being performed by the controller, the method comprising:
determining, by the controller, a first subset of the plurality of addressing lines and a second subset of the plurality of power lines; and
causing a flux storage device of the plurality of flux storage devices to reset by activating, by the controller, the first subset of the plurality of addressing lines and the second subset of the plurality of power lines simultaneously.

22. The method of claim 21, wherein the causing a flux storage device of the plurality of flux storage devices to reset includes causing a superconducting digital-to-analog converter (DAC) to reset.

23. The method of claim 22, wherein the causing a superconducting DAC to reset includes causing a superconducting DAC to reset, the superconducting DAC which includes a loop of superconducting material interrupted by an inductance, the inductance being at least one of a lumped-element inductance, a distributed inductance, a kinetic inductance, and an intrinsic inductance of the loop of superconducting material.

24. The method of claim 23, wherein the causing a superconducting DAC to reset, the superconducting DAC which includes a loop of superconducting material interrupted by an inductance, includes causing a superconducting DAC to reset, the superconducting DAC being inductively communicatively coupled to a programmable device via at least a portion of the inductance.

25. The method of claim 23, wherein the causing a superconducting DAC to reset includes causing a superconducting DAC to reset to a ground state.
